(19) United States
(12) Patent Application Publication
(10) Pub. No.: US 2026/0079181 A1
(43) Pub. Date: Mar. 19, 2026

(54) ELECTRICAL CIRCUIT TEST PROBE

(71) Applicant: William Robert Haller, Bethlehem, PA (US)

(72) Inventor: William Robert Haller, Bethlehem, PA (US)

(21) Appl. No.: 19/223,873

(22) Filed: May 30, 2025

Related U.S. Application Data
(60) Provisional application No. 63/731,716, filed on Jun. 3, 2024.

(51) Int. Cl. G01R 1/067

(52) U.S. Cl. CPC G01R 1/06788; G01R 1/06794

(57) ABSTRACT

An electrical circuit test probe may include a housing, a conductive test pin, a lens, and a lens positioning system which may include a rotatable lens mount and a pivotable lens support assembly. A system for measuring physical phenomena may include a measuring instrument, a probe, a lens, and a lens positioning system that provides an unobstructive view of a test point. A circuit for protecting a test probe circuit may include a first switch coupled to a battery, a second switch coupled to the first switch and responsive to a first control signal, a voltage limited first power source responsive to a second control signal, a voltage sensing circuit coupled to the first switch, a second power source coupled to the second switch and responsive to an enable signal, and a controller for providing the first control signal, the second control signal, and the enable signal.

### FIELD OF THE INVENTION

The present invention generally relates to electrical circuit test probes for connecting a circuit to an electrical measuring instrument, and more particularly to an apparatus which provides for the adjustable illumination and magnification of the probe tip and the circuit test point area.

### BACKGROUND OF THE INVENTION

Testing and troubleshooting of electrical printed circuit boards and other electrical apparatus usually requires the measurement of circuit voltages, currents, and other electrical phenomena. This task is commonly accomplished using a hand-held electrical circuit test probe for selectively connecting a circuit test point to an electronic measuring instrument such as a digital multimeter (DMM), an oscilloscope or other electrical measuring instrument. Other physical phenomena can also be measured at a test point using a suitable probe. The probe provides a representation of the physical phenomena to be measured. For example, temperature probes are used to measure the temperature of physical objects and near-field probes are used to measure electromagnetic radiation emitted from a circuit or a device.

A conventional circuit test probe may have an electrically insulating and cylindrically shaped housing which includes a conducting test pin which usually protrudes from the front end of the housing. The cylindrically shaped housing allows for the hand gripping of the housing by the user for the testing of the printed circuit board or other electrical apparatus. The protruding part of the test pin is used for making an electrical connection to the circuit test point.

The other end of the test pin is connected to the proximal end of a flexible wire which exits the back end of the insulated housing. The distal end of the flexible wire is fitted with an electrical connector for mating with the electrical measuring instrument. The test pin, wire and electrical connector combination electrically connect the circuit test point to the measuring instrument. Most test probes provide test pins which are rigidly affixed to the housing, and which have test pin tips which are slightly rounded.

In attempt to have the test pin electrically contact the circuit test point, the user may apply an excessive amount of force to the probe housing and therefore to the test pin. This excessive amount of force along with the rounded test pin tip may result in the test pin slipping off the intended test point and detrimentally making electrical contact between the desired circuit test point and other circuit conductors.

This is especially true for electrically probing high pin density integrated circuits having a small pin pitch. This excessive force on the probe tip may result in the probe tip slipping off the desired circuit test point and moving sideways making electrical contact between adjacent pins. This may result in a short circuit between the intended test point and an adjacent pin (or pins) or other electrical conductors, possibly damaging the integrated circuit.

It would also be advantageous for the user to be able to quickly replace a damaged conducting test pin. A damaged test pin may occur by having the user inadvertently dropping the test pin end of the probe onto a hard surface such as a floor.

Additionally, during the probing of electrical circuits and especially of integrated circuits having a small pin pitch, shadows produced by the probe housing may prevent the user from clearly seeing the circuit test point or test pin tip, and the user may therefore not be able to accurately place the test pin tip onto the intended circuit test point (or integrated circuit pin). This may result in the user unintentionally short-circuiting adjacent pins or other circuit conductors, again possibly damaging other parts of the circuit or the integrated circuit.

It would be advantageous therefore for the probe to be configured to provide uniform and shadowless illumination of the circuit test point and test pin tip. The probe should also provide the user with a means for easily adjusting the intensity of the illumination.

Also, during the probing of electrical circuits and especially of small pin pitch integrated circuits, it may be beneficial for the user to have a magnified view of the test point and the area surrounding the test point, in addition to the test pin tip. The magnified view will help with the placement of the test pin tip onto the desired circuit test point or integrated circuit pin and may further reduce eye strain.

It would also be helpful for the user to be able to quickly focus the image of the intended circuit test point and test pin tip while comfortably holding the test probe in any orientation.

It would also be beneficial for the user to be able to quickly change the magnification and field of view of the circuit test point and test pin tip image.

It would also be advantageous for the test probe to be portable and battery operated for field measurement applications. Preferably the test probe would provide protection against reverse battery installation and excessive battery voltage. A low battery detector would also be beneficial to the user.

The prior art includes many probes of various complexities to assist the technician or engineer in the measurement of circuit voltages, currents, and other electrical and physical phenomena.

For example, U.S. Pat. No. 5,672,964 issued to Vinci of Kirkwood, Pennsylvania granted in 1997 and titled “Voltage Probe Testing Device” discloses a test probe for primarily testing electrical circuits or components in motor vehicles. The test probe provides work area illumination. However, no magnifying lens is disclosed for magnifying the work area.

U.S. Pat. No. 6,377,0544 issued to Beha of Glottertal, Germany, granted in 2002 and titled “Test Device for Electrical Voltages with Integrated Illumination Unit” discloses an electrical test probe in the general shape of a pen having an illumination device for illuminating the work area. However, no magnifying lens is disclosed for magnifying the work area.

U.S. Pat. No. 7,208,932 issued to Chun of Santa Clara, California granted in 2007 and titled “Voltage Detector” discloses an electrical test probe having an LED and an LED lens for illuminating the test work area. The probe detects and measures the presence of EMF fields. A voltage multiplying circuit is also disclosed for powering the LED from a single 1.5-volt AA or AAA sized battery. However, no magnifying lens is disclosed for magnifying the work area.

Japanese Patent No. 4,393,238B2 titled “Probe Device with Loupe” granted in 2010 discloses a test probe having an illumination unit for illuminating the test point area and a loupe (magnifying lens) disposed on the body of the probe for magnifying and viewing the test point area. The loupe is supported by a support arm on the first end, and the second end of the support arm is rotatably affixed to a magnetic base. The probe body is further provided with a slide guide portion made from magnetic material. The magnetic base is placed on the top of the magnetic material which enables the magnetic base to slide along the magnetic material thus increasing or decreasing the distance from the magnifying lens to the test point area. Additionally, the rotating support arm is used to further focus the lens onto the test point area. Focusing the lens is through translation and rotation relative movements of the lens with respect to the test point area. Further disclosed is that the support arm may be constructed from a flexible material.

The disclosed system provides a magnified illuminated view of a test point area. However, the lens cannot be axially rotated around the probe body restricting the orientation of the probe housing with respect to the test point area. The user will have difficulty in comfortably holding the probe and focusing the lens. A two perpendicular axes lens positioning system is not disclosed.

U.S. Pat. No. 9,046,564 issued to Griffin of Detroit Lakes, Minnesota granted in 2015 and titled “Circuit Testing Device” discloses a test probe for testing electrical circuits in a vehicle and includes an LED for illuminating dark spaces. However, no magnifying lens is disclosed for magnifying an image of the work area and the test probe is externally powered requiring a detached power source.

U.S. Pat. No. 10,775,410 issued to Kraft et. al. of Monument, Colorado, granted in 2020 and titled “Lighted Probe for Electrical Testing Device” discloses a battery-operated test probe having a plurality of recessed LEDs oriented in a cross-like configuration and affixed to the probe housing for projecting light towards the tip of the probe and onto the work area. However, no magnifying lens is disclosed for magnifying an image of the work area, and further no lens is disclosed to focus the LED light emission onto the work area.

Thus, there is a need in the electrical testing industry for a test probe which allows the user to apply a controlled contact force for making an electrical connection between the test probe and the test point.

There is also a need to further provide a shadowless and uniform illumination of the test pin tip, the circuit test point, and the surrounding test point area, and which permits the user to adjust the intensity of the illumination projected onto the circuit test point.

There is yet another need for a battery operated portable electrical test probe to protect the probe's internal circuitry from reverse battery and over battery voltages.

Further, there is a need for a test probe which allows the user to quickly exchange one magnifying lens of a particular magnification with another magnifying lens having a different magnification for assisting the user in identifying the desired test point and making electrical contact of the test pin tip to the circuit test point.

There is also another need for a test probe which provides a lens positioning system which allows the user to focus the magnified image of the test pin tip and the intended circuit test point quickly and easily while comfortably holding the test probe in any orientation.

### SUMMARY OF THE INVENTION

To meet the needs identified above and others which will be apparent from a review of the current technology, and in view of its purposes, the present invention provides an electrical circuit test probe which is portable, battery operated, versatile, and easy to operate, and which may be used to accurately measure electrical phenomena of an electrical circuit.

In one embodiment of the invention, an electrical circuit test probe includes a spring-ably biased test pin for making electrical contact with the test point and configured to provide a controlled contact force between the test pin tip and the intended circuit test point.

In a further embodiment of the invention, the electrical circuit test probe has a circular array of electromagnetic radiators mounted within the housing and configured to project electromagnetic radiation outwards from the housing and incident upon the test point, the surrounding test point area, and the test pin tip.

In a further embodiment of the invention, the electrical circuit test probe has a circular array of electromagnetic radiators mounted within the housing and configured to project electromagnetic radiation incident on a converging lens for focusing the projected electromagnetic radiation outwards from the front of the housing and onto the test point, the surrounding test point area and test pin tip.

In some embodiments of the invention, the electromagnetic radiation emitted by the electromagnetic radiators may include visible light, ultraviolet radiation, or infrared radiation.

In some of the embodiments of the present invention, electromagnetic radiators may comprise light emitting diodes.

In a further aspect of the invention, the electrical circuit test probe comprises an electromagnetic intensity controller configured for controlling the intensity of the projected electromagnetic radiation emitted from the electromagnetic radiators. The intensity of the electromagnetic radiation emitted from the radiators is programmable by the user.

In yet another embodiment of the invention, the intensity of the electromagnetic radiation emitted from the electromagnetic radiators is responsive to the current supplied to the radiators.

In yet another embodiment of the invention, the intensity of the electromagnetic radiation emitted from the electromagnetic radiators is responsive to the current supplied to the radiators by a voltage controlled current source.

In yet another aspect of the invention, the intensity controller is programmable by the user and is further configured to supply a control signal to the voltage controlled current source for adjusting the amount of current supplied to the radiators thereby adjusting the intensity of the radiators.

In yet another embodiment of the invention, the intensity controller is responsive to a switch and is further configured to provide the voltage controlled current source control signal as a function of the number and duration of switch closures.

In another embodiment of the invention, the electrical circuit test probe comprises a magnifying lens for providing the user with a magnified view of the test pin tip, test point and the test point area.

In another embodiment of the invention, the electrical circuit test probe comprises a magnifying lens positioning system which includes an elongated housing having a longitudinal first axis of rotation. Rotatably affixed to the housing is a lens mount assembly which revolves around the longitudinal first axis. A lens support assembly is rotatably affixed to the lens mount assembly. Affixed to the lens support is a lens frame for holding a magnifying lens. The lens mount assembly and lens support assembly are configured to allow the lens support assembly to rotate around a second axis of rotation which is perpendicular to the longitudinal first axis of rotation.

In yet another aspect of the invention, the lens mount assembly and lens support assembly are further configured to allow the user to adjust the position of the magnifying lens to obtain an unobstructed magnified image of the probe test pin tip, the circuit test point and the area surrounding the test point irrespective of the spatial orientation of the elongated housing.

In yet another aspect of the invention, an elastomer element is affixed to the probe housing and is configured to be in frictional contact with the lens mount assembly. A compression spring is disposed between the probe housing and the lens mount assembly which forces the lens mount assembly to frictionally engage the elastomer element, thereby enabling the frictional rotation of the lens mount assembly around the longitudinal first axis of rotation.

In a further aspect of the invention, the electrical circuit test probe comprises a first switch coupled to the battery for delivering electrical power to the probe circuit, the first switch responsive to the polarity of the battery voltage thereby protecting the probe circuit from a reverse polarity battery installation.

In yet another aspect of the invention, the electrical circuit test probe comprises a second switch coupled to first switch for supplying electrical power to the probe circuit, the second switch being responsive to the magnitude of the battery voltage thereby protecting the probe circuit from excessive battery voltage.

In another embodiment of the invention, the electrical circuit test probe includes an elongated housing having a circular array of electromagnetic radiators affixed to the housing and configured to emit electromagnetic radiation in a direction away from the housing and incident upon the circuit test point. An optical element is removably attached to the housing and configured to focus the emitted electromagnetic radiation onto the test pin tip, the circuit test point, and the surrounding test point area. A conductive pin is provided for making electrical contact with the test point and is concentric with the circular array of electromagnetic radiators and is affixed to the optical element.

Other objects and advantages of the present invention will become clearer following a review of the specification and drawing. It is to be understood that both the foregoing general description and the following detailed description are exemplary, but are not restrictive, of the invention.

### BRIEF DESCRIPTION OF THE DRAWING

The above and other aspects and advantages of the invention will become more apparent upon consideration of the following detailed description, taken in conjunction with accompanying drawing. It is emphasized that, according to common practice, the various features of the drawing are not too scale. On the contrary, the dimensions of the various features are arbitrarily expanded or reduced for clarity, and in which reference characters refer to like parts throughout. Included in the drawing are the following figures:

FIG. 1 is a perspective view of an electrical circuit test probe in accordance with embodiments of the present invention;

FIG. 2 is a side elevation view of an electrical circuit test probe in accordance with embodiments of the present invention;

FIG. 3 is a front elevation view of an electrical circuit test probe in accordance with embodiments of the present invention;

FIG. 4 is an exploded perspective view of a probe housing shell in accordance with embodiments of the present invention;

FIG. 5 is an exploded perspective view of a probe housing shell insert assembly in accordance with embodiments of the present invention;

FIG. 6 is a bottom exploded perspective view of a probe housing insert body in accordance with embodiments of the present invention;

FIG. 7 is an exploded perspective view of the lens mount assembly in accordance with embodiments of the present invention;

FIG. 8 is a cross-sectional view of the lens mount assembly in accordance with embodiments of the present invention;

FIG. 9 is an exploded front view of a probe tip assembly in accordance with embodiments of the present invention;

FIG. 10 is an exploded back perspective view of a probe tip assembly in accordance with embodiments of the present invention;

FIG. 11 is the cross-sectional view of a probe tip assembly in accordance with embodiments of the present invention;

FIG. 12 is a perspective view of a probe tip in accordance with embodiments of the present invention;

FIG. 13 is the cross-sectional view of a probe tip in accordance with embodiments of the present invention illustrating the refractive back of the probe tip;

FIG. 14 is a perspective view of a lens support assembly in accordance with embodiments of the present invention;

FIG. 15 is a bottom perspective view of a lens support assembly in accordance with embodiments of the present invention;

FIG. 16 is a partial side elevation cross sectional view of an electrical circuit test probe illustrating the frictional contact between the nonembedded O-ring surface and the outward facing flange surface in accordance with embodiments of the present invention;

FIG. 17 is a block diagram of a control circuit in accordance with embodiments of the present invention;

FIG. 18 is a circuit schematic of a control circuit in accordance with embodiments of the present invention;

FIG. 19 is a power-on flow chart of exemplary methods for practicing the present invention, in accordance with embodiments of the present invention;

FIGS. 20A-20D are the operational flow charts of exemplary methods for practicing the present invention, in accordance with embodiments of the present invention;

FIGS. 21A and 21B are timing diagrams of the operational states of the present invention, in accordance with embodiments of the present invention;

FIG. 22 illustrates two orientations of the probe position with respect to the eye of the user.

### DETAILED DESCRIPTION OF THE INVENTION

In the following description, several specific details are presented to provide a thorough understanding of embodiments of the inventive concepts disclosed herein. One skilled in the relevant art will recognize, however, that embodiments of the inventive concepts disclosed herein can be practiced without one or more of the specific details, or in combination with other components, etc. In other instances, well-known implementations or operations are not shown or described in detail to avoid obscuring aspects of various embodiments of the inventive concepts disclosed herein.

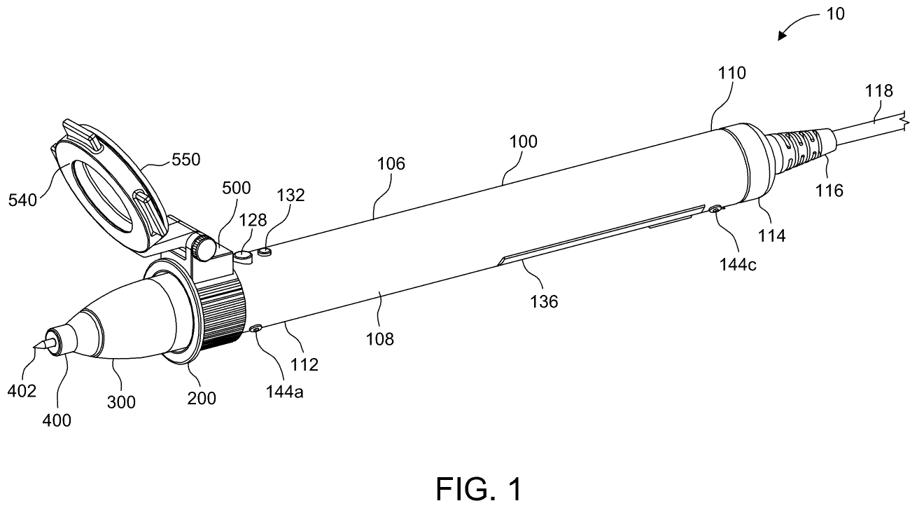

Referring to FIGS. 1-3, a representation of an electrical circuit test probe 10 is shown in accordance with embodiments of the present invention having a cylindrically shaped main probe housing 100 having a longitudinal first axis 104, a lens mount assembly 200, a probe tip assembly 300, a probe tip 400 and a lens support assembly 500.

It is understood that the housing may be of any convenient geometrical shape and may include a housing having a square or hexagonal or other type of cross-sections.

The probe housing 100 has a top surface 106, a bottom surface 108, a back end 110 and a front end 112. The back end 110 of the probe housing 100 has an attached end cap 114 and a wire strain relief 116.

Strain relief 116 is attached to the end cap 114. Strain relief 116 relieves the bending strain of the probe wire 118 during the normal use of the test probe 10.

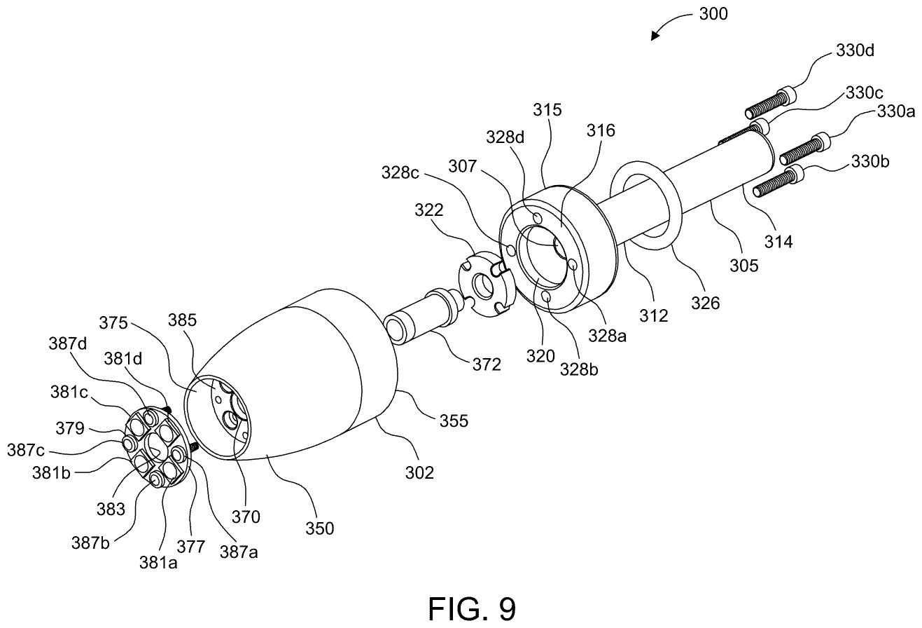

The probe wire 118 passes through strain relief 116 and end cap 114 and is electrically connected to electrically conducting pin receptacle 372 (shown in FIG. 9).

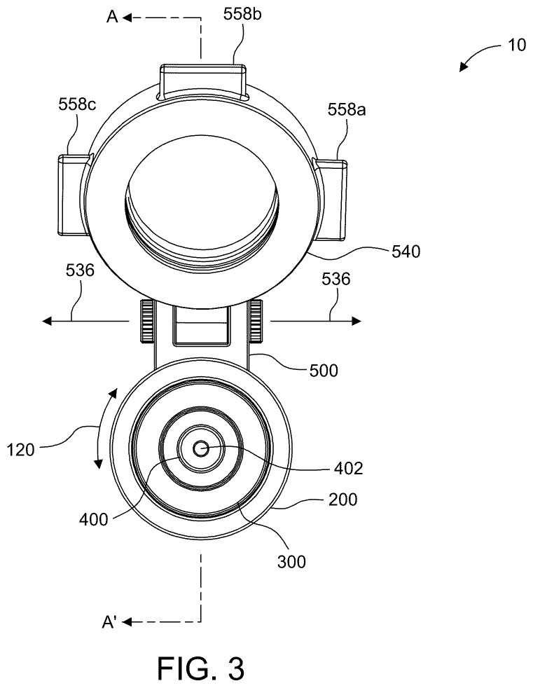

As will be more fully disclosed below, lens mount assembly 200 is rotatably affixed to probe housing 100 and rotates about longitudinal first axis 104 in the directions indicated by arrows 120 (see FIG. 3).

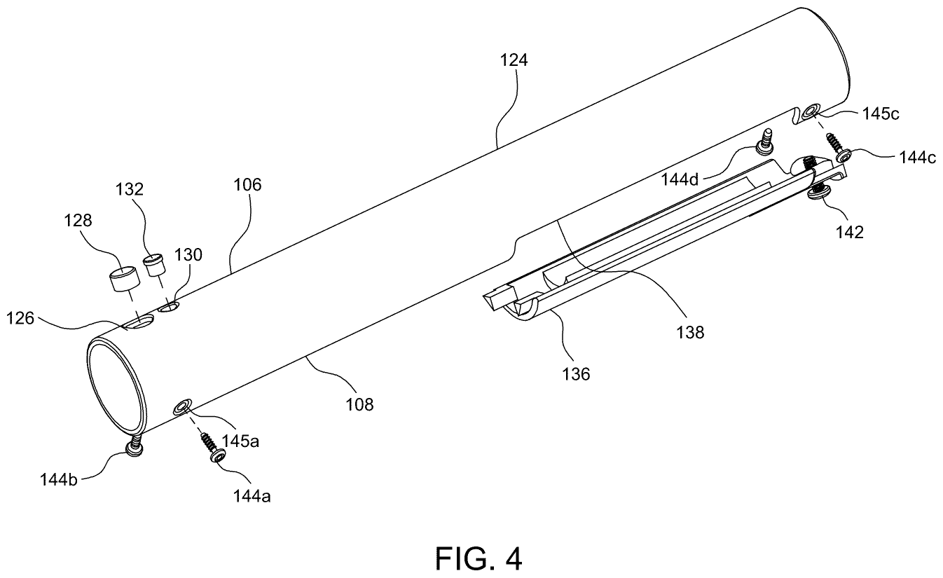

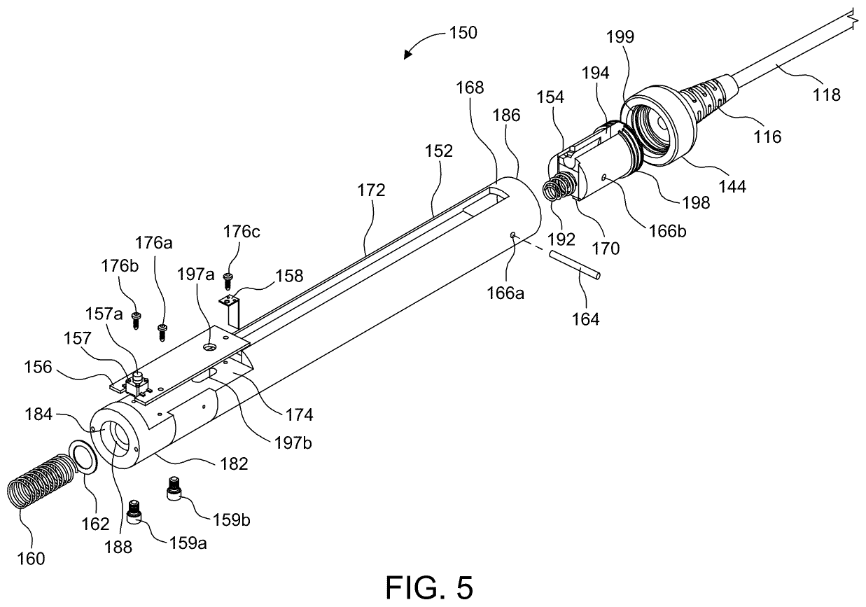

Referring additionally to FIG. 4, probe housing 100 further comprises a cylindrically shaped probe housing shell 124 having a switch button hole 126 formed on the top surface 106. Hole 126 is sized to allow switch button 128 to freely move in the vertical direction. Switch button 128 is affixed to the stem 157a of a pushbutton switch 157 (both shown in FIG. 5). Vertically depressing switch button 128 closes the attached pushbutton switch 157. Located rearward of and in line with hole 126 is status LED lens mounting hole 130 having an affixed transparent status LED lens 132.

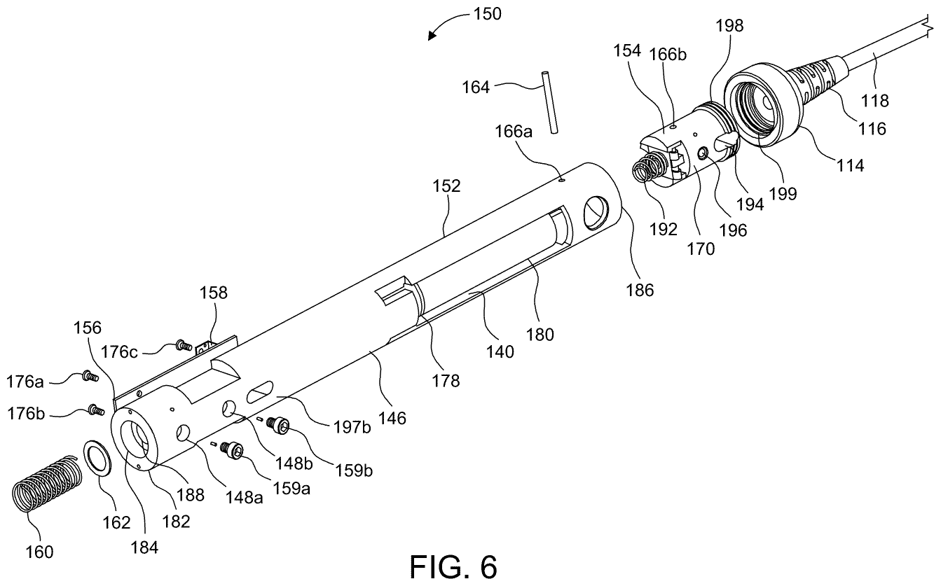

Removably affixed to the bottom surface 108 of housing shell 124 is battery access panel 136. When removed from housing 100, access panel 136 exposes battery opening 138 and permits the installation or removal of batteries from battery compartment 140 (shown in FIG. 6) of probe housing insert body 152. Once the batteries have been installed or removed, access panel 136 may then be secured to the probe housing 100 with a removeable access panel screw 142.

Referring additionally to FIGS. 5 and 6, probe housing 100 further comprises a cylindrically shaped housing shell insert assembly 150. Housing shell insert assembly 150 comprises a cylindrical shaped insert body 152, wire bushing 154, printed circuit board 156 having the pushbutton switch 157 affixed to the top surface of the printed circuit board 156, a compression spring 160, washer 162, and roll pin 164.

Insert assembly 150 is positioned within, and is concentric with housing shell 124. Housing shell 124 is affixed to insert assembly 150 by screws 144a, b, c, and d passing through holes 145a, b (not shown), c, and d (not shown) respectively of housing shell 124 and into insert body 152.

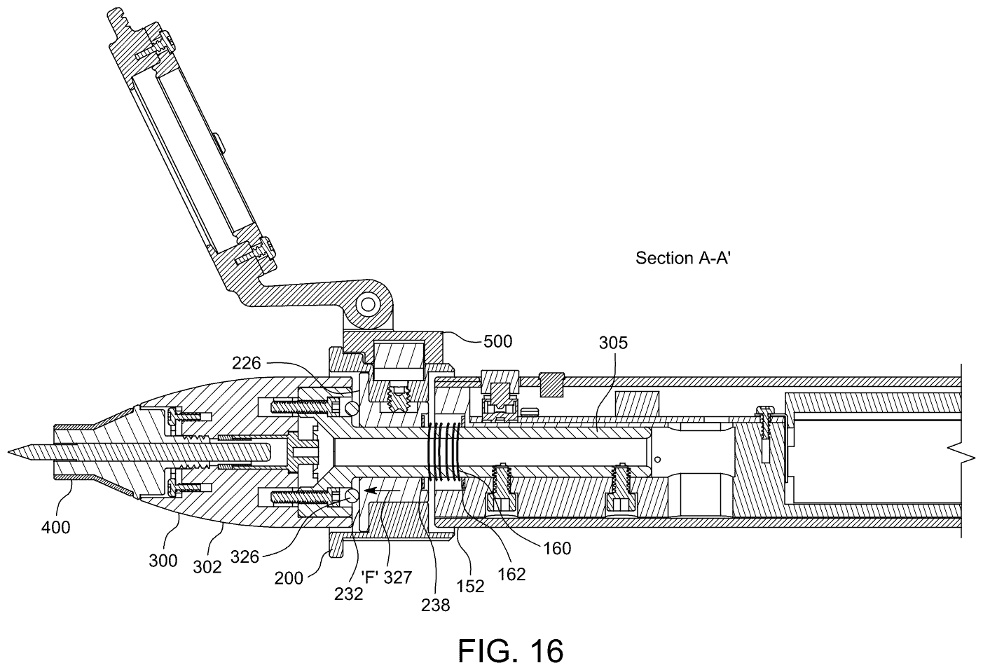

The front end 182 of insert body 152 has formed a cylindrical spring chamber 184 concentric with insert body 152 for accepting the washer 162 and the compression spring 160. The rear surface of chamber 184 has further formed a shaft hole 188 which is concentric with, and extends into, insert body 152. Shaft hole 188 extends from the rear surface of chamber 184 into insert body 152 for accepting shaft 305 (shown in FIG. 16). Shaft 305 passes through spring 160 and washer 162. Washer 162 is positioned between the rear surface of chamber 184 and spring 160. Spring 160 and washer 162 are concentric with shaft hole 188, and therefore shaft 305.

Formed on the side of insert body 152 is an insert body roll pin mounting hole 166a. Longitudinally formed on the top surface 168 of insert body 152 is wire conduit 172 and a printed circuit board mounting platform 174. The printed circuit board 156 is affixed to the platform 174 by printed circuit screws 176a, b, and c. Screw 176c also conductively affixes the positive battery contact 158 to the printed circuit board 156.

Insert body 152 has further formed on the bottom 146 battery compartment 140 enclosing a first battery 178 and a second battery 180 (see FIG. 6). Batteries 178 and 180 are positioned so that the positive terminal of the second battery 180 makes electrical contact with the negative terminal of the first battery 178 thereby connecting the first battery 178 and second battery 180 in series. Contact 158 extends into battery compartment 140 and makes electrical contact with the positive terminal of first battery 178 and printed circuit board 156.

A cylindrically shaped wiring bushing 154 is provided which is concentric with and inserted into the back end 186 of insert body 152. Wire bushing roll pin mounting hole 166b is formed on the side of the wiring bushing 154. Having the wiring bushing 154 inserted into insert body 152, holes 166a and 166b are aligned and the roll pin 164 may be forcibly inserted into the holes 166a and 166b affixing the wire bushing 154 to the insert body 152.

A conventional battery negative terminal spring contact 192 is affixed to the front end of the wire bushing 154 and makes electrical connection with the negative battery terminal of the second battery 180. A wire (not shown) follows along wire conduit 172 and electrically connects the spring contact 192 to the printed circuit board 156. Thus, the installed series connected batteries 180 and 178 are connected to the printed circuit board 156.

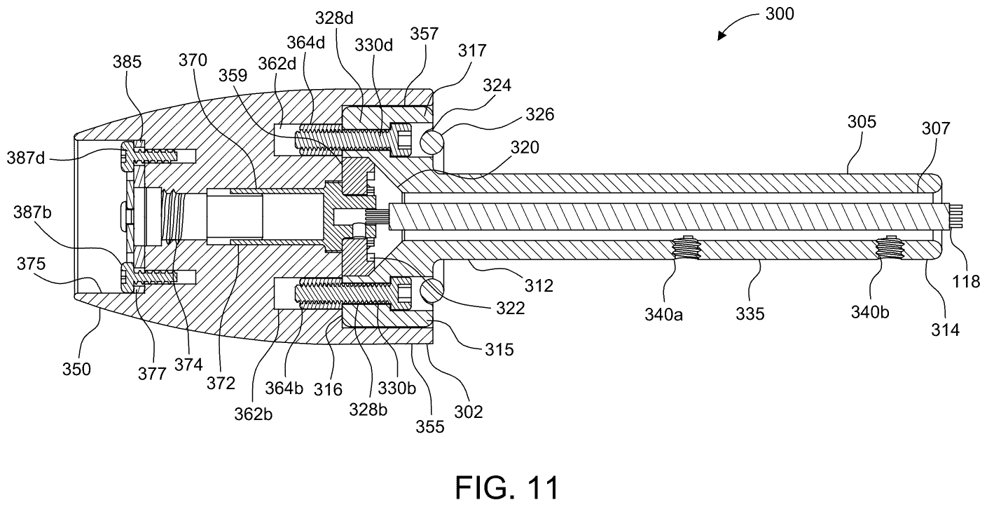

A wire access slot 194 is further formed near the back end of wire bushing 154. Wire 118 is inserted through both the wire strain relief 116 and end cap 114 upwards through wire access slot 194 and into the wire conduit 172, through printed circuit board wire access hole 197a and into wire slot 197b, and further through the shaft bore 307 on the back end 314 of shaft 305 making electrical connection with pin receptacle 372 (shown in FIG. 11).

A threaded insert 196 is press fitted affixed to the bottom surface 170 of the wire bushing 154 for accepting the removable access panel screw 142. Wire bushing 154 has male threads 198 formed on the outer surface of the back end of the wire bushing 154 for thread-ably engaging the female threads 199 of the end cap 114, thereby affixing the end cap 114 to the wire bushing 154.

Insert 152 has further formed on bottom surface 146 holes 148a and 148b for accepting shaft mounting screws 159a and 159b respectively. Screws 159a and 159b thread into threaded holes 340a and 340b (shown in FIG. 11) of shaft 305 respectively affixing shaft 305 to insert body 152.

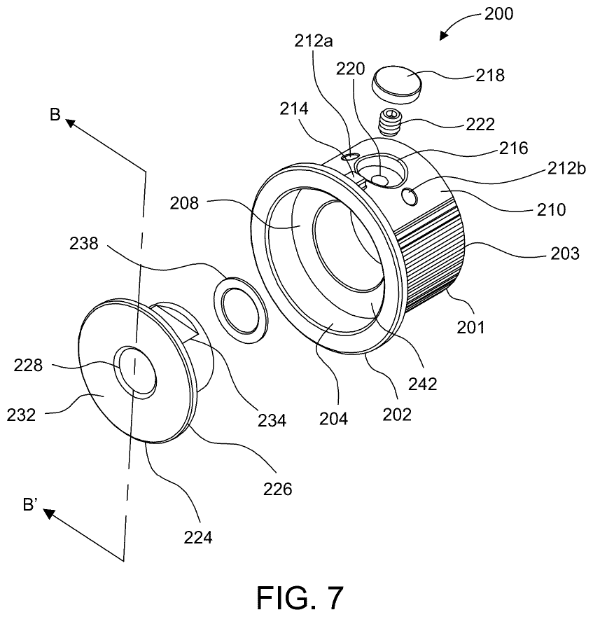

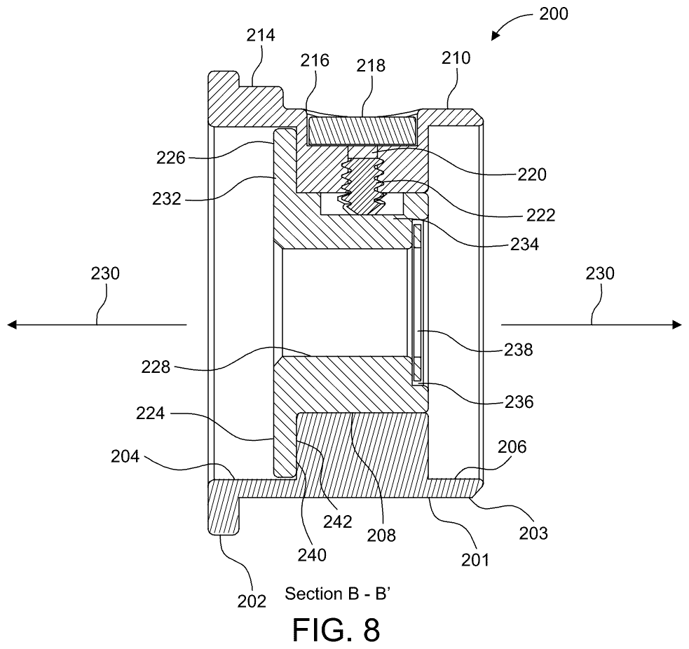

Referring to FIGS. 7 and 8, the lens mount assembly 200 is shown having a cylindrically shaped bushing housing 201 having a front end 202 and a back end 203, a front end located cylindrical shaped bushing cavity 204, a back end located cylindrical shaped housing cavity 206, and a bushing mounting hole 208.

Located on the curved top surface 210 of the bushing housing 201 are alignment holes 212a and 212b and alignment boss 214. Located also on the top surface 210 between the alignment holes 212a and 212b is a cylindrical shaped magnet mounting blind hole 216 formed to accommodate the cylindrical shaped magnet 218. Concentric with the magnet mounting blind hole 216 is threaded through hole 220 which accepts set screw 222.

The lens mount assembly 200 further comprises a cylindrical shaped flanged bushing 224 which is concentric with bushing housing 201 and having an axis 230 which is coincident with axis 104, a flange 226, and a bore 228. Flange 226 further has an outward facing flange surface 232.

A flat 234 is further formed on the top surface of the bushing 224 for engaging the bottom surface of threaded set screw 222. Further formed on the back end of flanged bushing 224 is a cylindrical washer chamber 236 to accommodate washer 238. Flanged bushing 224 is force fitted into bushing mounting hole 208 having the inward facing surface 240 of flange 226 contacting the outward facing surface 242 of bushing cavity 204. Bore 228 and washer 238 are concentric with bushing housing 201.

Set screw 222 is threaded into hole 220 and affixes flanged bushing 224 to bushing housing 201. Magnet 218 is affixed inside of blind hole 216 using conventional fasteners which may include glue.

Referring additionally to FIGS. 9-11, the probe tip assembly 300 is shown having a probe tip housing 302, a shaft 305 having a bore 307 and a front end 312 and a back end 314. Formed on the front end 312 is a shaft flange 315 having a front surface 316 and a back surface 317. Formed on the front surface 316 is a conical shaped chamber 320 for accommodating pin receptacle holding washer 322. Pin receptacle holding washer 322 is concentric with shaft 305 and compressively affixes pin receptacle 372 to the probe tip housing 302.

Formed on the back surface 317 is a groove 324 for accommodating an elastomer element such as an O-ring 326. The shape of the groove 324 is configured to conform to the shape of the elastomer element. For example, the elastomer element may be a washer and the groove would be configured to conform to the shape of the washer.

The depth of the O-ring groove 324 allows for the partial insertion of the O-ring 326 into the O-ring groove 324 and places approximately one-half of O-ring 326 within the groove 324. The other half of the O-ring 326 extends past the back surface 317 of the shaft flange 315 and engages the outward facing flange surface 232 as shown in FIG. 16.

The O-ring 326 material may include nitrile, polytetrafluoroethylene (PTFE) ethylene propylene diene monomer (EPDM), silicone, Viton, or other elastomer like material.

The diameter of the O-ring groove 324 is slightly greater than the diameter of the O-ring 326, and therefore the O-ring 326 is stretched into the O-ring groove 324 thereby affixing the O-ring 326 to the shaft 305.

As more fully explained in reference to FIG. 16, O-ring 326 is further longitudinally held in place by the force ‘F’ 327 exerted onto the outside facing surface 232 of flange 226 by the compression spring 160. O-ring 326 is therefore compressed between the O-ring groove 324 and the outside facing surface 232 of flange 226, thus providing a frictional force to resist rotation of the lens mount assembly 200.

Further formed on the back surface 317 are bolt circle positioned flange mounting screw holes 328a, b, c, and d formed to accommodate flange mounting screws 330a, b, c, and d respectively.

Further formed on the bottom surface 335 of shaft 305 are threaded shaft mounting holes 340a and 340b. Shaft mounting screws 159a and 159b engage shaft mounting holes 340a and 340b respectively for affixing shaft 305 to insert body 152.

Probe tip housing 302 is shown having a front end 350 and a back end 355. Formed on the back end 355 is a cylindrical shaped flange chamber 357 having a back surface 359. Formed on the back surface 359 are four mounting holes 362a (not shown), b, c, and d which accommodate threaded inserts 364a (not shown), b, c, and d respectively. Shaft 305 is affixed to the probe tip housing 302 with flange mounting screws 330a, b, c, and d having back surface 359 contact front surface 316 of flange 315.

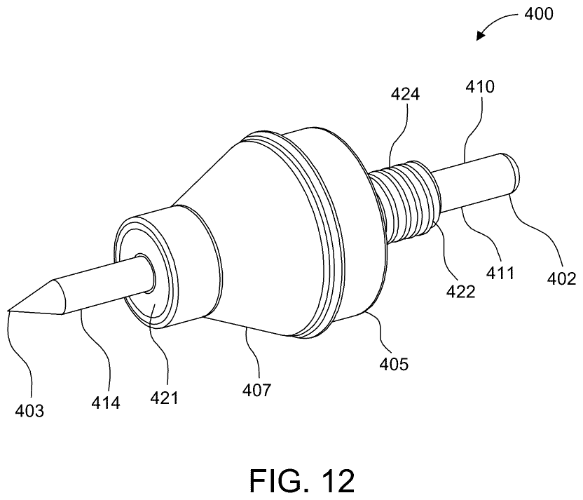

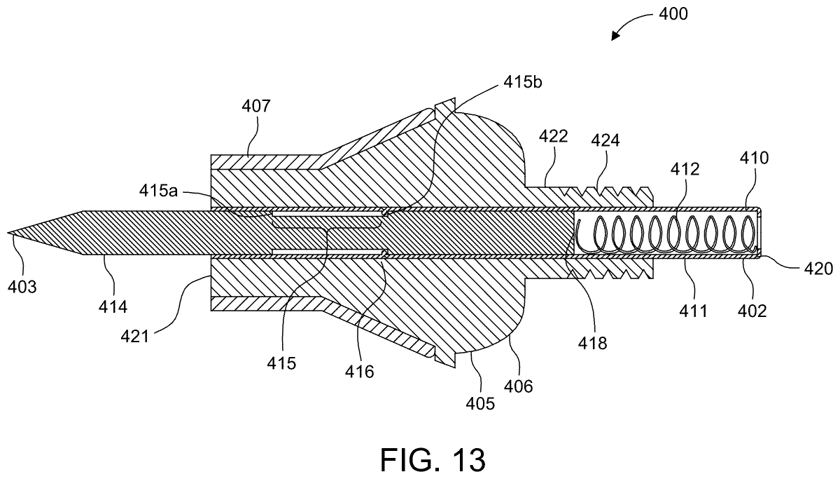

Further formed on the back surface 359 is pin receptacle mounting hole 370 which is concentric with shaft 305 for accommodating pin receptacle 372. Pin receptacle 372 is forced fitted into pin receptacle mounting hole 370. The front end of pin receptacle mounting hole 370 has a threaded portion 374 for accepting the threaded portion 424 of lens stem 422 of the probe tip 400 (see FIGS. 12 and 13).

The front end 350 of probe tip housing 302 has further formed a cylindrical chamber 375 for accommodating light emitting diode circular array 377. Light emitting diode circular array 377 comprises a round printed circuit board 379 having individual light emitting diodes 381a, b, c, and d. Although only a single light emitting diode circular array 377 is shown, additional circular arrays of light emitting diodes may be included. Other light sources may be used in place of the individual light emitting diodes 381a, b, c, and d such as xenon lights, halogen lights and fiber optic lights or a combination thereof. The LEDs may further produce light of different wavelengths (colors).

The printed circuit board 379 is concentric with shaft 305 having a hole 383 for accommodating the lens stem 422 of the probe tip 400. Printed circuit board 379 is affixed to the back surface 385 by conventional screws 387a, b, c, and d.

The light emitting diodes 381a, b, c, and d are circularly arrayed around the stem hole 383 and mounted on the outside surface of the printed circuit board 379 for outwardly projecting light from the front end 350. The outwardly projecting light from the light emitting diode array 377 is incident upon the back surface 406 of lens 405 (see FIG. 13). Although only four light emitting diodes 381a, b, c, and d, are illustrated, it is understood that any number of LEDs may be used.

The circularly arrayed individual light emitting diodes 381a, b, c, and d, along with lens 405 provides for uniform and shadowless illumination of the sharp test pin tip 403 of the conducting pin 402 and the surrounding test point area.

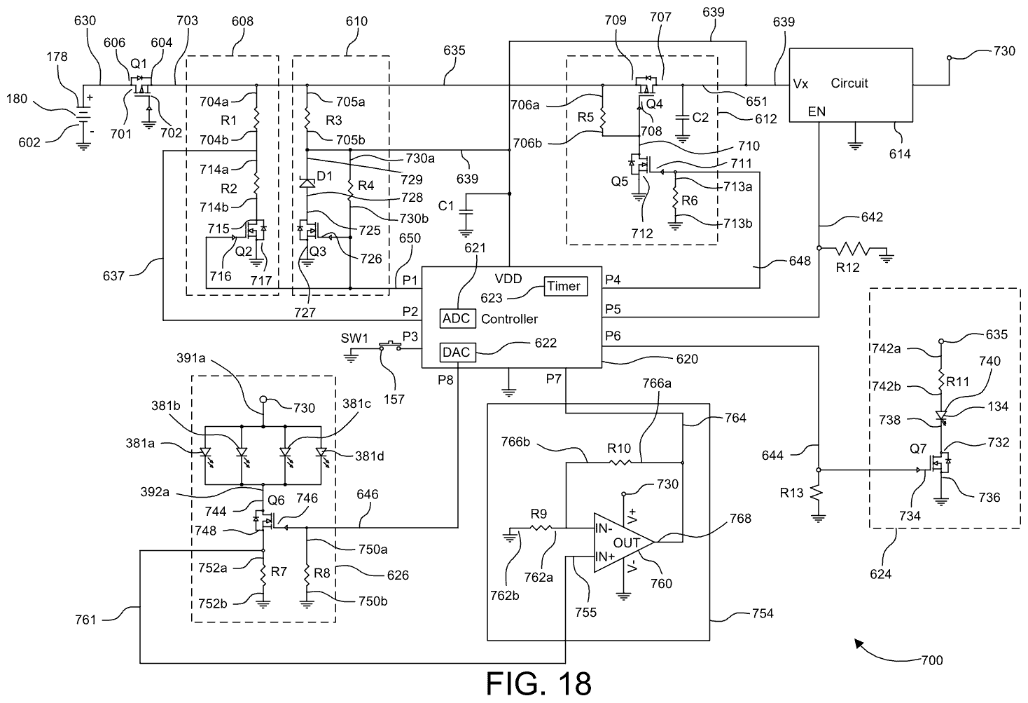

Two wires 391a and 392a (shown in FIG. 18) are electrically connected to the backside of the printed circuit board 379 and connect the light emitting diode array 377 to the printed circuit board 156.

The path followed for the two wires includes wire 391a through wire access holes 391 and the wire 392a through wire access hole 392. Both wires 391a and 392a then follow a path through the pin receptacle holding washer 322, further through the conical shaped chamber 320, further through the shaft bore 307, further through the insert body wire slot 197b and further through printed circuit board 156 access hole 197a and finally being electrically connected to the printed circuit board 156. For clarity, the wires 391a and 392a are not shown.

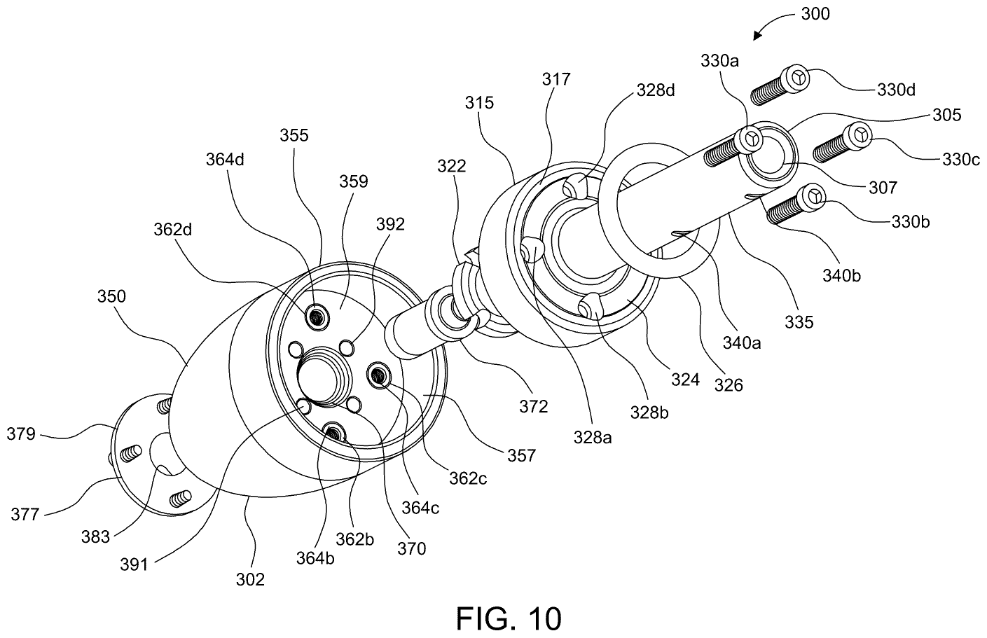

As shown in FIGS. 10 and 11, the shaft flange 315 is affixed to the probe tip housing 302 by screws 330a, b, c, and d being threaded into threaded inserts 364a, b, c, and d respectively. The O-ring 326 is partially embedded within O-ring groove 324 having a portion of the O-ring extending past the back surface 317 of flange 315.

Referring to FIGS. 12-13, the probe tip 400 is shown having a cylindrically shaped electrically conducting test pin 402, a lens 405 having a back surface 406, and a conically shaped translucent light shield 407. The translucent light shield 407 allows light emitted by the four light emitting diodes 381a, b, c, and d to partially illuminate the test point area and is affixed to the outside surface of lens 405.

The conducting test pin 402 comprises a barrel body 410 having an outside surface 411, an internal compression spring 412, and an internal plunger 414 having a necked down portion 415. The plunger further comprises a sharp test pin tip 403 for making electrical contact with desired test point of the circuit.

Barrel body 410 has formed on the circumference of the outside surface 411 an indent 416 which cooperates with the front and back ends 415a and 415b respectively of the necked down portion 415 of plunger 414 to restrict the axial longitudinal movement of the plunger 414 within the barrel body 410.

The compression spring 412 is positioned within the barrel body 410 and is positioned between the back end 418 of the plunger 414 and the inside back surface 420 of barrel body 410. Compression spring 412 normally biases the plunger 414 in an extended position as shown in FIG. 13. As the user forcibly engages the test pin tip 403 with the test point, the spring 412 compresses and the plunger 414 is forcibly retracted into the barrel 410 until the end 415a contacts indent 416.

The compressive force of compression spring 412 follows Hooke's Law, and therefore slightly compressing spring 412 results in a reduced force exerted by the test pin tip 403 onto the circuit test point. Alternately, substantially compressing spring 412 results in an increased force exerted by the test pin tip 403 onto the circuit test point.

The contact force exerted by the test pin tip 403 onto the circuit test point is a function of the distance the compression spring 412 is compressed and the spring constant of compression spring 412. Once contact is made between the test pin tip 403 and the circuit test point, the user controls the force exerted by the test pin tip 403 and the circuit test point by manually moving the housing 100 closer to (increases the contact force), or further from (decreases the contact force) the circuit test point.

Thus, the user may easily control the amount of force exerted by the test pin tip 403 onto the circuit test point and can easily apply just enough controlled force necessary to electrically contact the test pin tip 403 to the circuit test point. The spring constant of compression spring 412 and the distance of the necked down portion 415 determine the maximum controlled force the user may apply between the test pin tip 403 and the circuit test point.

Additionally, increasing the controlled force exerted on the test pin tip may also force the test pin tip 403 to slightly penetrate the surface layer of the circuit test point thereby affixing the tip 403 and preventing the tip 403 from slipping off the intended circuit test point. The test pin tip 403 material is made from a hard material which may include beryllium copper, and may be gold plated to increase surface conductivity of the test pin tip 403. The hard material may easily penetrate the softer printed circuit board copper traces or integrated circuit pins For fine pitch integrated circuit testing, shorting between adjacent pins during testing of the integrated circuit is of concern and is prevented by controllably forcing the penetration of the tip 403 into the circuit test point.

The lens 405 may be constructed from glass or other transparent material such as plexiglass for bending light and is conically shaped on the front end so as not to visually obstruct the placement of the tip 403 onto the desired circuit test point.

The back surface 406 of lens 405 is configured to refract the visible light emitted by the light emitting diode array 377 through the lens front surface 421, thus simultaneously illuminating the test pin tip 403, the circuit test point, and the surrounding test point area.

The back surface 406 has also formed a cylindrically shaped stem 422 which extends backwards towards the inside back surface 420 of barrel body 410. Threads 424 are formed on the end of stem 422 and engage threads 374 of the pin mounting hole 370.

Pin 402 is concentric with, and affixed to, the lens 405. The back portion of pin 402 extends past the back surface 406 of lens 405 and is formed to be forcibly inserted into pin receptacle 372 as shown in FIG. 16 as the probe tip threaded portion 424 is threaded into threads 374 of hole 370. Thus, the probe tip 400 is affixed to the probe tip assembly 300. If the probe tip 400 should become damaged, the probe tip 400 may be replaced by unthreading the probe tip 400 from the probe tip assembly 300.

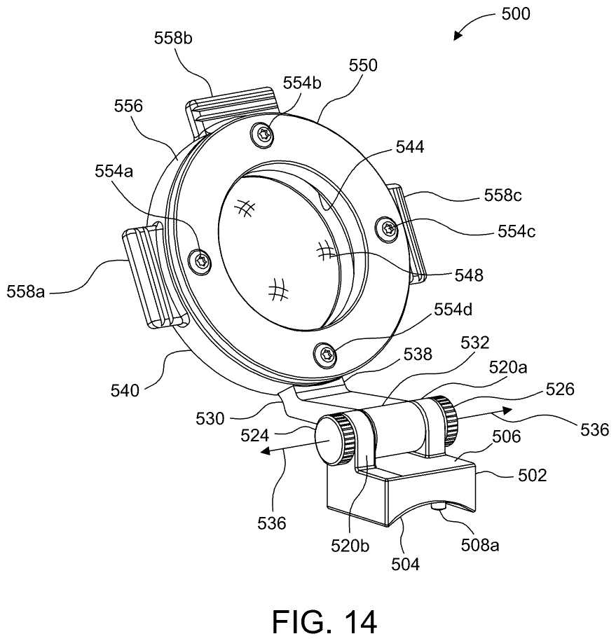

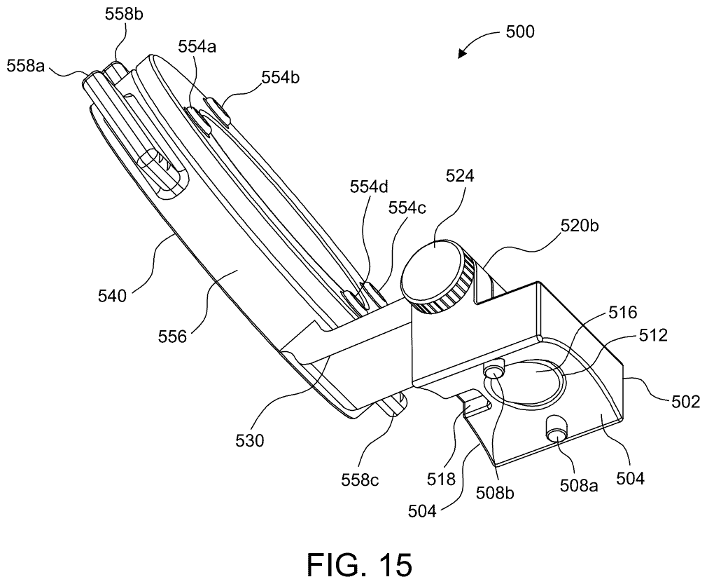

Referring to FIGS. 14-15, lens support assembly 500 is shown having lens frame support 502. Lens frame support 502 comprises a curved bottom mounting surface 504 and a top surface platform 506. The profile of curve mounting surface 504 matches the profile of curved top surface 210 of lens mount assembly 200.

Formed on the bottom surface 504 are two downwardly projecting alignment pins 508a and 508b. Further formed on the bottom surface 504 is a cylindrical shaped magnet cavity 512 formed to accommodate magnet 516. Magnet 516 is affixed to the lens frame support 502 using conventional means, such as glue. Further formed on the bottom surface 504 is alignment notch 518. Alignment pins 508a and 508b are removably inserted into holes 212a and 212b respectively of lens mount assembly 200, and alignment notch 518 is formed to accommodate alignment boss 214.

Further, magnet 516 is concentric with magnet 218 having the magnetic poles of magnets 516 and 218 arranged so that there exists a magnetic force of attraction between magnets 516 and 218. With the alignment pins 508a and 508b inserted into holes 212a and 212b respectively, and alignment boss 214 inserted into alignment notch 518, the magnetic force of attraction between the magnets 516 and 218 removably affixes the lens support assembly 500 to the lens mount assembly 200. Lens support assembly 500 may be removed from the lens mount assembly 200 by having the user exert an upward force thereby separating magnet 516 from magnet 218.

The lens frame support 502 has further formed on platform 506 two upwardly projecting supporting uprights 520a and 520b. Upright 520b has a hole (not shown) to accommodate a conventional internally threaded binding barrel 524 and upright 520a has a hole (not shown) to accommodate a matching externally threaded machine screw 526 for thread-ably attaching to the binding barrel 524.

Inserted between the supporting uprights 520a and 520b is lens frame support arm 530 having a cylindrical shaped bearing element 532 having a hole 534 (not shown) for accepting the binding barrel 524. The hole 534 is concentric with the binding barrel 524 and machine screw 526, and with the binding barrel 524 and screw 526 tightened the lens frame support arm 530 may resistively rotate about the axis 536.

Formed on the opposite end 538 of lens frame support arm 530 is cylindrically shaped lens frame 540. Lens frame 540 has an internal rabbet 544 for receiving the magnifying lens 548.

Lens cover 550 is affixed to frame 540 with screws 554a, b, c, and d having the magnifying lens 548 affixed to, and sandwiched between, the lens frame 540 and lens cover 550. Lens frame 540 has further formed on the outside ring surface 556 of lens frame 540 frame fingers 558a, b, and c for adjusting the angular position of the magnifying lens 548 without the need to touch the lens 548 itself. It is thus understood that the magnifying lens 548 is pivotally supported by lens support assembly 500.

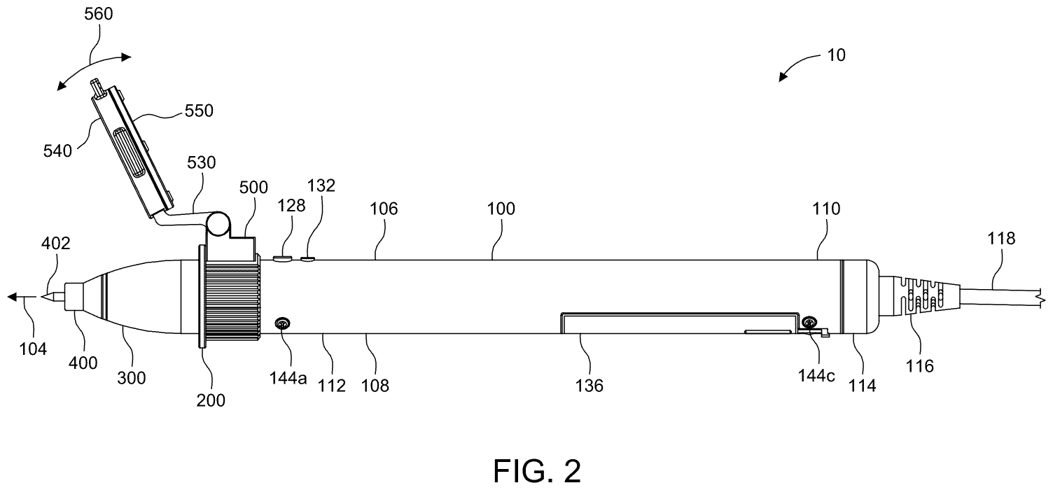

Therefore, magnifying lens 548 may rotate in the direction 560 as shown in FIG. 2 about axis 536 and may also independently rotate in the direction 120 as shown in FIG. 3 about axis 104 via the rotation of the lens mount assembly 200. Axes 536 and 104 are configured to be perpendicular to each other.

It is thus understood that lens 548 may independently rotate around perpendicular axes 104 and 536. The lens mount assembly 200 and the lens support assembly 500 are configured so that the user may position lens 548 to obtain an unobstructed magnified view of the probe tip 403 making electrical contact with the circuit test point area irrespective of the probe 10 spatial orientation.

Referring additionally to FIG. 16, a partial side elevation cross sectional view of probe 10 is shown having shaft 305 mounted to the tip housing 302 and the insert body 152. Further shown is probe tip 400 threaded into the probe tip assembly 300 and lens support assembly 500 magnetically affixed to lens mount assembly 200.

Also shown is spring 160 compressed between the washers 162 and 238. The compressed spring 160 forces the outward facing flange surface 232 against the nonembedded outside surface of O-ring 326 and provides for a frictional contact between flange surface 232 and the outside surface of O-ring 326. The spring constant of spring 160 is chosen to prevent non-attended rotation of the lens mount assembly 200 about axis 104 but allows for the forcible rotation by the user for positioning lens 548 around axis 104.

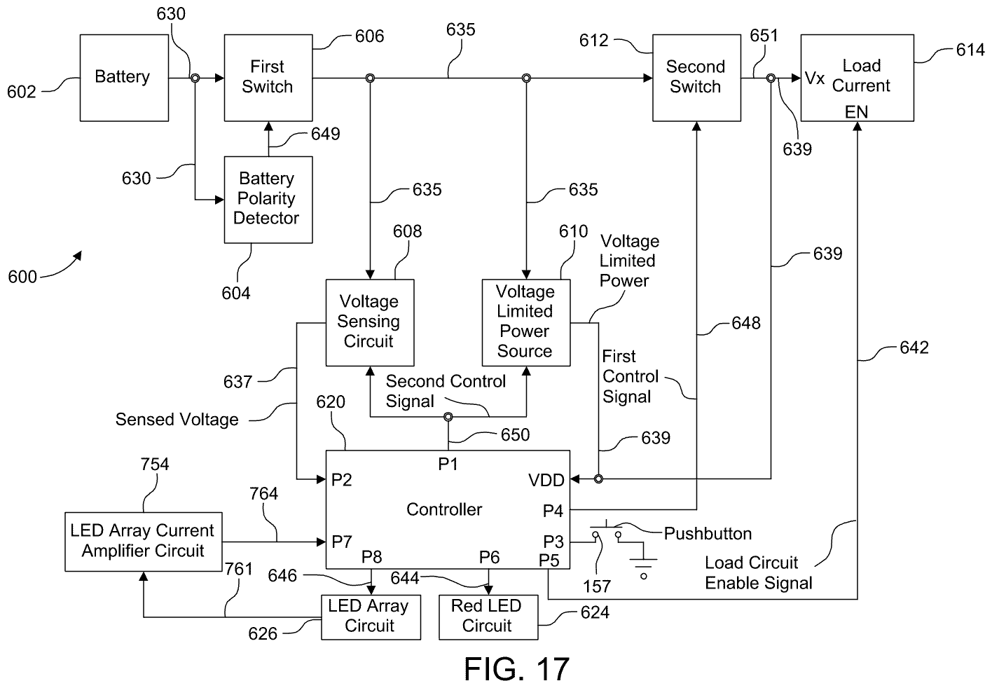

Referring to FIG. 17, a system block diagram 600 of the electronic circuit for the electric circuit test probe 10 is shown having a battery power source 602, a battery polarity detector 604, a first power switch 606, a voltage sensing circuit 608, a voltage limited power source 610, a second power switch 612, a load circuit 614, a controller 620, a red light emitting diode circuit 624, a light emitting diode array circuit 626, LED array current amplifier circuit 754 and the pushbutton switch 157. The battery power source 602 may comprise the series connection of first battery 178 and the second battery 180, and the LED array circuit 626 may comprise light emitting diode array circuit 379.

Additionally, the load circuit 614 may comprise a second power source such as a switching regulator circuit to provide electrical power to the LED array circuit 626 and other probe 10 circuitry (further disclosed in reference to FIG. 18).

Block diagram 600 further comprises battery power bus 630 which connects the battery 602 to the first switch 606 and the battery polarity detector 604.

Control signal 649 flows from the battery polarity detector 604 to the first switch 606, and the ON-OFF state of switch 606 is responsive to the control signal 649. If the battery polarity is functionally correct, the detector 604 places the first switch 606 in the ON state via control signal 649. With switch 606 placed in the ON state the battery power bus 630 is connected to the main power bus 635.

The main power bus 635 is connected to the voltage sensing circuit 608, voltage limited power source 610, and to the second switch 612.

The voltage sensing circuit 608 is configured to immediately sense the voltage on the main power bus 635 and send a sensed voltage signal 637 to an input pin P2 on the controller 620. The sensed voltage signal 637 gives an indication of the magnitude of the battery voltage of the battery power source 602.

Similarly, the voltage limited power source 610 is configured to immediately provide voltage limited power onto the voltage limited power bus 639. The voltage limited power bus 639 is connected to the controller 620 via power pin VDD, the second switch power bus 651, and the load circuit 614. The voltage of the voltage limited power bus 639 is limited to an acceptable value which does not exceed the operational voltage limits of the controller 620 and the load circuit 614.

The voltage sensing circuit 608 and the voltage limited power source 610 may be simultaneously enabled or disabled by the output pin P1 of the controller 620 via the second control signal 650. However, it may be advantageous in some applications to control voltage sensing circuit 608 separately from voltage limited power source 610.

The ON-OFF state of the second switch 612 is responsive to the output pin P4 of controller 620 via the first control signal 648. With the second switch placed in the ON state by the first control signal 648, the main power bus 635 is connected to the second switch power bus 651 and to the voltage limited power bus 639.

The controller 620 is connected to the red LED circuit 624 and outputs a red LED control signal 644 from output pin P6 to the red LED circuit 624 for controlling the ON-OFF state of the red LED 134 (shown in FIG. 18). The controller 620 is also connected to the LED array circuit 626 and outputs an LED array light intensity signal 646 from the output pin P8 to the LED array circuit 626 for controlling the intensity of light being emitted by the LED diode array 377.

The LED array circuit 626 also senses the amount of current flowing through LEDs 381a-381d and provides a signal 761 indicative of the magnitude of this current. LED array current amplifier circuit 754 inputs the signal 761 and provides an amplified signal 764 representing the magnitude of the LED array current. The controller 620 inputs the amplified signal 764 via input pin P7.

Controller 620 is connected to pushbutton switch 157 via pin P3 and is configured to determine the number and duration of switch 157 depressions. Controller 620 controls the ON OFF operation of load circuit 614 via the output pin P5 and the load circuit enable signal 642.

Referring to FIG. 18, a circuit schematic 700 representing an embodiment of the block diagram 600 is shown having a battery source 602 comprising the first battery 178 in series with the second battery 180. The negative terminal of battery 180 makes contact with the negative terminal spring contact 192 and is connected to the ground.

The positive terminal of battery 178 connects to the drain terminal 701 of P-type MOSFET transistor Q1 via battery power bus 630. Gate terminal 702 of Q1 is connected to ground and the source terminal 703 of Q1 is connected to terminal 704a of resistor R1, terminal 705a of resistor R3, terminal 706a of resistor R5, and the source terminal 709 of P-type MOSFET transistor Q4 and via main power bus 635. The drain terminal 707 of Q4 forms the second switch power bus 651.

Terminal 706b of resistor R5 connects to gate terminal 708 of P-type MOSFET transistor Q4 and the drain terminal 710 of N-type MOSFET transistor Q5. The source terminal 712 of Q5 is connected to the ground. Gate terminal 711 of Q5 connects to terminal 713a of resistor R6 and the other terminal 713b of resistor R6 is connected to the ground.

A port output pin P4 of controller 620 supplies the first control signal 648 to the junction of the gate terminal 711 of Q5 and terminal 713a of R6. Resistor R6 is configured as a conventional pull-down resistor which maintains the first control signal 648 connected to ground unless otherwise determined by the output port pin P4 of controller 620, maintaining the second switch 612 in the OFF condition until turned on by the first control signal 648. The drain terminal 707 of Q4 connects to the second switch power bus 651 which further connects to both the load circuit 614 and to the voltage limited power bus 639. Control signal 648 may turn ON or OFF transistor Q5 which in turn may turn ON or OFF transistor Q4 respectively.

Terminal 704b of R1 connects to terminal 714a of R2 and supplies the sensed battery voltage 637 to a port input pin P2 of controller 620. The pin P2 is internally connected to an analog to digital (ADC) converter 621 of controller 620. Terminal 714b of resistor R2 connects to the drain terminal 715 of N-type MOSFET transistor Q2. Gate terminal 716 of Q2 is connected to gate terminal 726 of N-type MOSFET transistor Q3 and connects to a port output pin P1 of the controller 620 which supplies the second control signal 650. The second control signal 650 may turn ON or OFF transistors Q2 and Q3.

The source terminal 727 of Q3 is connected to ground, and the drain terminal 725 of Q3 is connected to the anode terminal 728 of Zener diode D1. The cathode terminal 729 of D1 connects to terminal 705b of resistor R3 and to the terminal 730a of resistor R4. The connection of the terminal 705b of resistor R3, the cathode terminal 729 of D1 and the terminal 730a of resistor R4 forms the voltage limited power bus 639.

The ON-OFF states of transistors Q2 and Q3 are controlled by the second control signal 650. Having the second control signal 650 turn ON transistor Q2, resistors R1 and R2 form a resistor divider which samples the voltage of bus 635. Having the second control signal 650 also turn ON transistor Q3, the anode of Zener diode D1 is connected to the ground. The Zener diode D1 is then in series with resistor R3, and voltage limited power is delivered to voltage limited power bus 639 through R3 with the bus 639 voltage limited by the Zener voltage of diode D1.

The voltage limited power bus 639 connects to the power input terminal VDD of controller 620, the second switch power bus 651 and the power terminal Vx of load circuit 614.

The controller 620 is further configured to provide a load circuit enable signal 642 from a port output pin P5 to load circuit 614. The enable signal 642 enables the load circuit 614 to perform its intended function. Pull-down resistor R12 is configured as a conventional pull-down resistor and maintains the enable signal 642 at ground unless determined by the output pin P5.

For example, load circuit 614 may be configured as a boost switching regulator circuit of conventional design and, when enabled, produces a regulated output voltage 730 independently of the battery voltage produced by the series connection of batteries 178 and 180.

Pushbutton switch 157 connects to a port input pin P3 of controller 620. Input pin P3 has an internal pull-up resistor enabled. Controller 620 is configured to detect the number of and duration of switch 157 depressions.

The controller 620 is further configured to provide the red LED control signal 644 to the red LED circuit 624. The control signal 644 connects to gate terminal 734 of N-type MOSFET transistor Q7. The source terminal 736 of Q7 is connected to ground and the drain terminal 732 of Q7 is connected to the cathode terminal 738 of red LED diode 134. The anode terminal 740 of diode 134 is connected to terminal 742b of resistor R11, the other terminal 742a of resistor R11 is connected to the main power bus 635. Pull-down resistor R13 maintains the control signal 644 at ground unless determined by the port output pin P6 of controller 620.

Controller 620 may turn on LED 134 by providing a control signal 644 which turns on transistor Q7.

The controller 620 is further configured to provide an analog LED array control signal 646 from its internal digital-to-analog converter 622. Control signal 646 is applied to terminal 750a of R8 and to gate terminal 746 of N-type MOSFET Q6. The source terminal 748 of Q8 connects to terminal 752a of resistor R7 and to the positive input terminal 755 of conventional op-amp 760. The other terminal 752b of resistor R7 connects to ground.

Terminal 750b of R8 is connected to the ground. Resistor R8 is configured as a conventional pull-down resistor and maintains the control signal 646 at ground unless determined by the port output pin P8.

The drain terminal 744 of Q6 is connected to all cathode terminals of the LED diodes 381a, b, c, and d. All the anodes of the LED diodes 381a, b, c, and d are connected to regulated output voltage 730 provided by load circuit 614.

It is well known that the intensity of emitted light from an LED is a function of the amount of current flowing through the LED. Increasing the amount of current flowing through the LED increases the intensity of emitted light. Thus, the intensity of emitted light may be controlled by adjusting the amount of LED current.

Transistor Q6 is configured as a voltage controlled current source and therefore Q6 may adjust the amount of current flowing through the LED array diodes 381a, b, c, and d as a function of the gate 746 to source 748 voltage, which is subsequently determined by the analog voltage LED array control signal 646. Resistor R7 provides negative feedback and may help to linearize the response of LED array diodes 381a, b, c, and d current to the analog voltage LED array control signal 646.

The array control signal 646 may be derived from the internal digital to analog converter (DAC) 622 of controller 620. The array control signal 646 represents an analog output signal for controlling the amount of current flowing through the LED diodes 381a, b, c, and d. Thus controller 620 and transistor Q6 are configured as an adjustable current source for varying the diodes 381a, b, c, and d current and hence the intensity of the LED array 377 produced light.

Alternately, a digital pulse width modulated signal may be substituted for the analog array control signal 646 for adjusting the light intensity of the LED diodes 381a, b, c, and d. Controller 620 may configure timer 623 to produce the digital pulse width modulated signal 646 (instead of the analog control signal 646). Using pulse width modulation to adjust the light intensity of LED diodes is well established in the art.

LED array circuit 626 is configured to produce a voltage across resistor R7 proportional to the total current flowing through the LED array diodes 381a, b, c, and d. The terminal 752a of resistor R7 is connected to the positive input terminal 755 of op-amp 760, and the other terminal 752b of resistor R7 is connected to ground.

The negative input terminal of op-amp 760 is connected to terminal 762a of resistor R9 and terminal 766b of resistor R10. Terminal 762b of resistor R9 is connected to the ground.

Terminal 766a of resistor R10 is connected to the output terminal 768 of op-amp 760 and the output terminal 768 provides a voltage signal 764 proportional to the total current flowing through the LED array diodes 381a, b, c, and d.

The signal 764 connects to an analog to digital port input pin P7 of controller 620. Controller 620 is configured to input and then convert the signal 764 into a digital signal using the analog-to-digital converter 621.

The op-amp may be powered from the regulated output voltage 730 produced by the load circuit 614. Op-amp 760 is configured as a conventional non-inverting amplifier.

Controller 620 may be a model number ATtiny417 microcontroller manufactured by Microchip Technology Inc. of Chandler, Arizona.

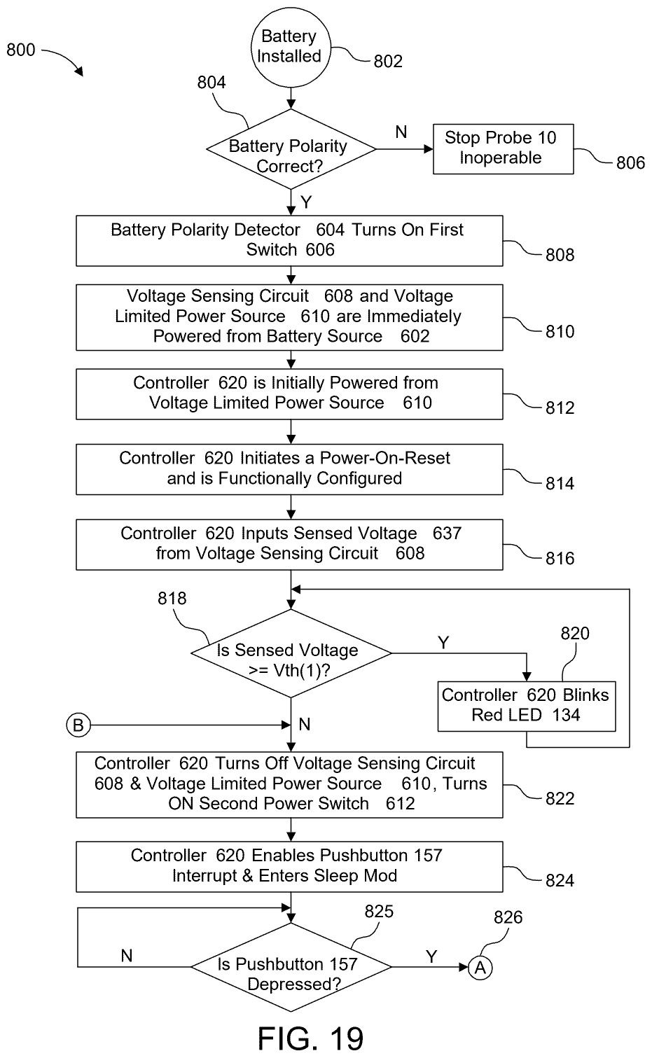

Referring additionally to FIG. 19, the power-on flowchart 800 of the electronic circuit 700 is shown and begins first with the user installing both the first battery 178 and then the second battery 180 into the battery compartment 140 as shown in step 802. If the batteries 178 and 180 are properly installed, the positive terminal of the first battery 178 makes electrical contact with the positive battery contact 158, the positive terminal of the second battery 180 makes electrical contact with the negative terminal of the first battery 178, and the negative battery terminal of the second battery 180 makes electrical contact with the negative battery contact 192.

Immediately upon proper battery installation, transistor Q1 switches ON only if the polarity of the installed batteries is correct and supplies battery power 630 to the main power bus 635 as shown in step 808. If the batteries 178 and 180 are not installed properly, transistor Q1 switches OFF and battery power 630 is not applied to main power bus 635 as shown in step 806. Circuit 700 in step 806 is inoperable. It is therefore understood that transistor Q1 functions as both the first switch 606 and battery polarity detector 604, protecting the circuit 700 from reverse battery voltage installation.

Having battery power 630 applied to main power bus 635, power is immediately applied to both gate terminal 716 of transistor Q2 and gate terminal 726 of Q3 through R3 and R4 and therefore immediately turns ON both transistors Q2 and Q3 and thus immediately powering ON both the voltage sensing circuit 608 and the voltage limited power source 610 as indicated in step 810 without waiting for controller 620 to complete its power-on-reset (POR) procedure. At this point terminal P1 is a high impedance input.

With Q2 switched ON, terminal 714b of R2 is connected to the ground. Resistors R1 and R2 are now in series forming a resistor divider having the junction of terminal 704b of R1 and terminal 714a of R2 providing the sensed battery voltage signal 637 which is proportional to the applied battery voltage.

With Q3 switched ON, the anode terminal 728 of Zener diode D1 is connected to ground. The cathode terminal 729 of Zener diode D1 is further connected to terminal 705b of resistor R3. The voltage at the junction of the cathode terminal 729 of Zener diode D1, the terminal 730a of resistor R4, and terminal 705b of resistor R3 is limited by the Zener diode voltage specification of D1. If the battery voltage of battery power source 602 exceeds the Zener diode voltage specification of D1, D1 is forced into its Zener region of operation thereby limiting the voltage of the power bus 639, thus immediately providing voltage limited power onto bus 639. The available current for the voltage limited power bus 639 is initially determined by resistor R3.

The voltage limited power bus 639 supplies power to the controller 620 as indicated in step 812, and additionally to the load circuit 614 and onto the second switch power bus 651. However, the load circuit 614 is not enabled currently because of the pull-down resistor R12 and thus circuit 614 remains in the OFF condition. The voltage limited power source 610 only needs to power the controller 620.

In response to power being immediately supplied onto the voltage limited power bus 639, controller 620 begins a power-on-reset (POR) procedure and is subsequently functionally configured for the application as shown in step 814. During the period of power-on-reset the input and output pins P1-P8 of controller 620 are all configured as high impedance inputs.

During this period, pull-down resistors R6, R8, R12, and R13 establish the power-on-reset state (ground) for output pins P4, P8, P5, P6, respectively. Resistors R6, R8, R12, and R13 passively maintain the second power switch 612, the LED array circuit 626, the load circuit 614, and the red LED circuit in the OFF condition during the controller 620 power-on-reset state.

The series connection of R3 and R4 establishes the power-on-reset state for the gate terminals 716 and 726 of transistors Q2 and Q3 respectively, immediately placing both transistors in the ON state during the first application of voltage onto the main power bus 635.

With the voltage limited power source 610 immediately enabled upon application of battery power 603, the controller 620 and the load circuit 614 are immediately protected from excessive battery voltage.

After the completion of step 814, controller 620 is functionally configured to control the ON-OFF state of the second power switch 612 with the first control signal 648, to control the ON-OFF state of the load circuit 614 with the load control enable signal 642, to control the ON-OFF state of the voltage sensing circuit 608 and voltage limited power source 610 with the second control signal 650, to input the sensed battery voltage signal 637, to determine if the pushbutton switch 157 is depressed, to control the ON-OFF state of the red LED 134 with the red led control signal 644, to control the LED array circuit 626 with the led array control signal 646 for turning ON or OFF the array LEDs 381a, b, c, and d, at a preprogrammed light intensity, and to input the op-amp 760 output signal 764.

The controller 620 within step 814 is further configured to actively place the second power switch 612 in the OFF condition, to actively place the load circuit 614 in the OFF condition, to actively turn ON the voltage sensing circuit 608 and voltage limited power source 610, to actively place the LED array circuit 626 in the OFF condition, to actively place the red led circuit 624 in the OFF condition, and to actively input the op-amp output signal 762.

Thus, having the second switch in the OFF condition and the load circuit 614 being powered from the voltage limited power source 610 maintains the input voltage to the load circuit 614 at or below the voltage limit of the voltage limited power source 610.

In steps 816 and 818, the controller 620 then inputs the sensed battery voltage signal 637 and determines if the sensed battery voltage signal 637 exceeds a preprogrammed threshold value Vth(1).

If the sensed battery voltage exceeds the preprogrammed threshold value Vth(1), the controller 620 in step 820 continually blinks LED 134 thereby visually warning the user that the series voltage of batteries 178 and 180 exceed the recommended voltage rating for properly operating the electrical circuit test probe 10 and the currently installed batteries need to be replaced with batteries having the recommended voltage ratings.

For example, the nominal voltage for single AAA size NiMH (nickel metal hydride) battery ranges from about 0.9 to 1.4 volts, the nominal voltage for a single AAA size ZnMnO2 (alkaline) battery ranges from about 0.9 to 1.5 volts, and the nominal voltage for a single AAA size LiFeS2 (lithium iron disulfide) ranges from 0.8 to 1.8 volts. Any two of these different batteries in series produces a series battery voltage between 1.6 to 3.6 volts.

However, the nominal voltage for a single AAA size LiFePO4 (lithium-iron phosphate) ranges from 2.5 to 3.75 volts. Mistakenly using two of these battery types of the same AAA size in series will produce a series battery voltage ranging from 5 to 7.5 volts which may exceed the maximum operating voltage of the load circuit 614.

As an example, the load circuit 614 may be a switching regulator part number TPS 61022 manufactured by Texas Instruments of Dallas, Texas for providing a regulated voltage output voltage 730. According to this part's specification, the absolute maximum voltage range for the input power voltage is 7 volts maximum and −0.3 volts minimum. Any voltages exceeding this range may cause permanent damage to the part.

Thus, mistakenly installing two LiFePO4 batteries in series of the same size as the recommended batteries may exceed the absolute maximum voltage for the input power of the switching regulator part TPS61022 potentially damaging the part. Similarly, without reverse battery polarity protection, placing batteries in series and in the reverse order will certainly exceed the minimum −0.3 voltage specification, again potentially damaging the part.

The red LED circuit 624 is powered from main power bus 635 instead of being powered directly from the controller 620 thus minimizing the power drawn from the voltage limited power bus 639. An audible warning may also be provided to the user in addition to, or as a replacement for, red LED 134 and is well known in the art.

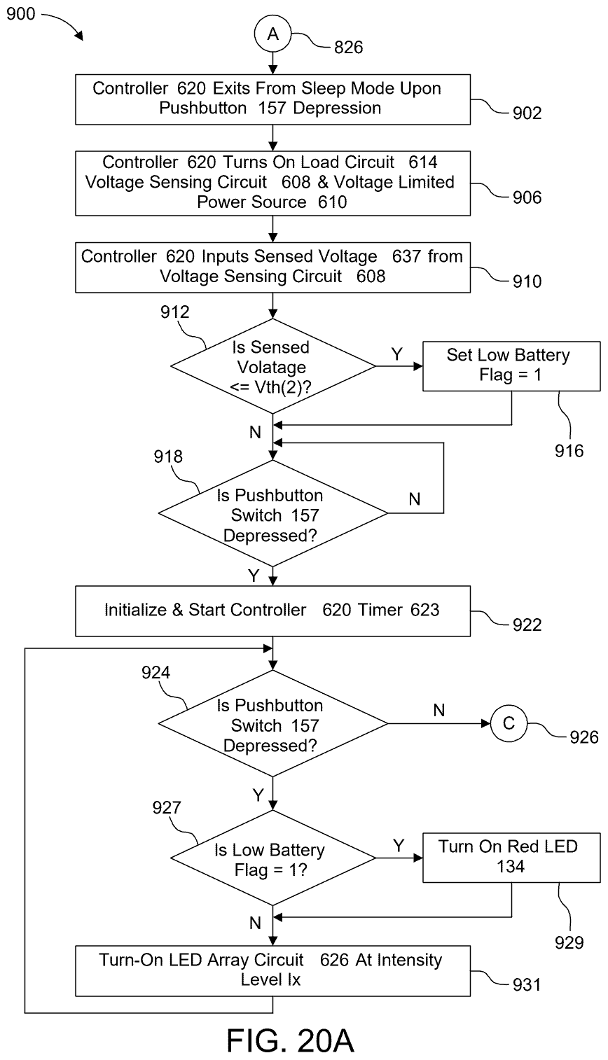

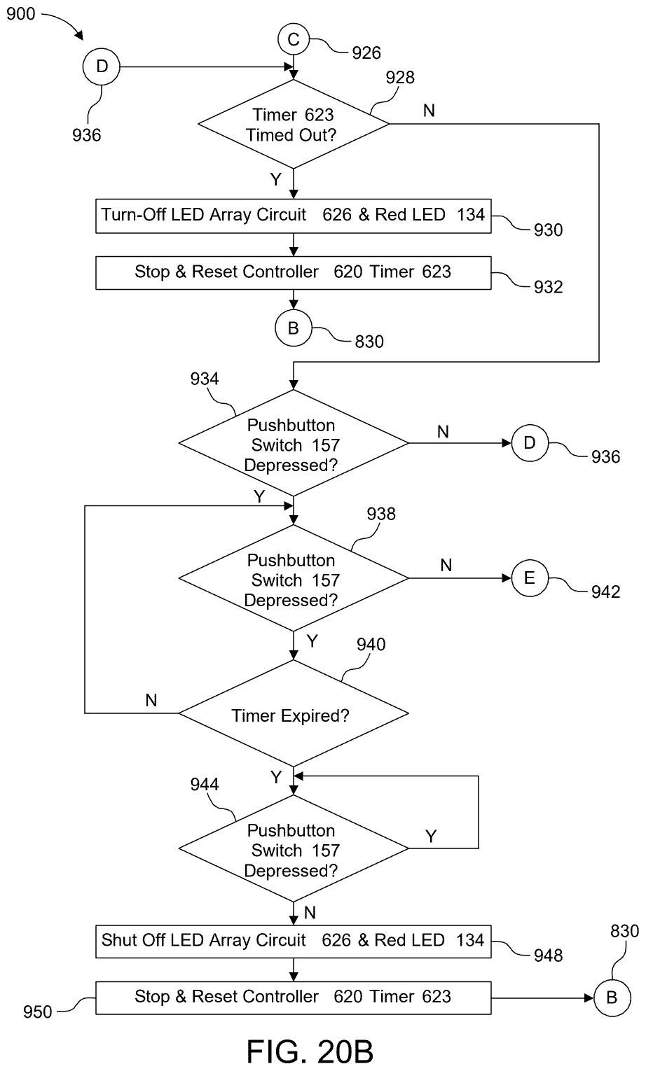

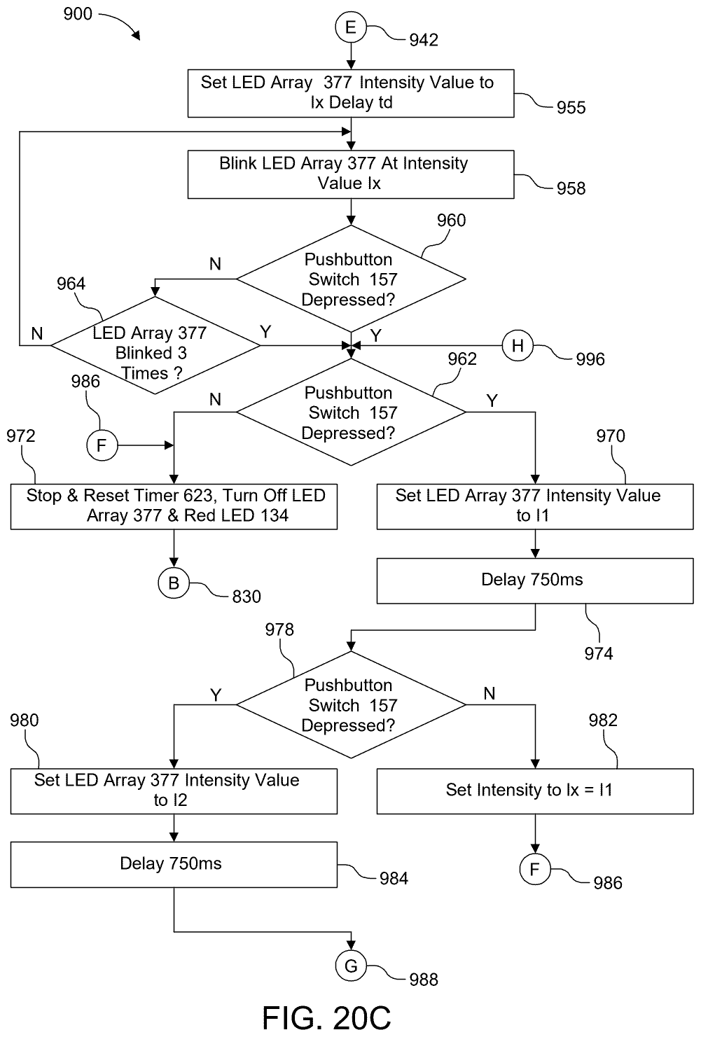

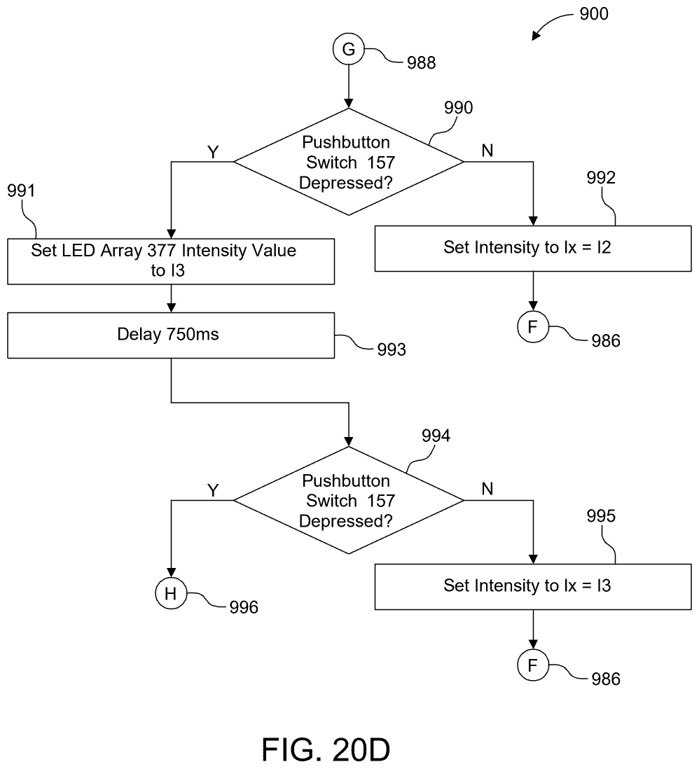

If the sensed voltage is below Vth(1), program flow continues from step 818 to step 822. Also entry point ‘B’ directs program flow to step 822 from the operational flow chart shown in FIGS. 20A-20D.

In step 822, if the sensed voltage 637 does not exceed the preprogrammed threshold value Vth(1), the controller 620 turns OFF the voltage sensing circuit 608 by turning OFF Q2 and turns OFF the voltage limited power source 610 by turning OFF Q3 via second control signal 650 (the controller 620 physically grounds the port output pin P1). Controller 620 also turns ON the second power switch 612.

Turning OFF Q3 effectively opens the connection to diode D1 reducing the current through D1 to a very low value thus saving battery power. With D1 open circuited, current now flows through the series resistors R3 and R4 to ground through pin P1 (P1 is connected to the ground internally by controller 620). Resistor R4 may have a high resistance decreasing its current and having a minimal effect on battery life.

In step 822 controller 620 actively turns on the second power switch 612 by turning on transistor Q5 with the first control signal 648. Q5 then turns on Q4 which connects the main power bus 635 to the second switch power bus 651 and voltage limited power bus 639. After step 822, the controller 620 is directly powered from the main power bus 635 and has sufficient power to power its required peripherals. In essence, the higher valued resistor R3 is placed in parallel with the much lower drain to source resistance of transistor Q4 allowing controller 620 to consume more current than that available from the limited voltage power source 610. Controller 620 is now selectively powered from the second power switch 612. Program flow then continues to step 824.

In step 824, controller 620 is configured to internally enable a hardware interrupt for pushbutton switch 157. Controller 620 then immediately enters a minimal power consumption sleep state and maintains the sleep state until pushbutton 157 is depressed as indicated by step 825.

During the sleep state, circuit 700 is in the quiescent state and consumes minimal power and may draw only the leakage currents associated with the controller 620, load circuit 614, voltage sensing circuit 608, voltage limited power source 610, red LED circuit 624 and second power switch 612. Current flows through resistors R3 and R4 (pin P1 is grounded to turn OFF voltage sensing circuit 608 and the voltage limited power source 610 via Q2 and Q3). Current also flows through resistors R5 and R6. The values of resistors R3, R4, R5 and R6 may be chosen to minimize power consumption for circuit 700 for the period that the controller 620 is in sleep mode.

Thus, the electronic circuit schematic 700 immediately provides for both battery reverse polarity and battery overvoltage protection for load circuit 614. For a reverse battery polarity installation, circuit 700 places the probe 10 into an inoperable state. For battery overvoltage, the circuit 700 blinks the red LED 134 and maintains both the second power switch 612 and load circuit 614 in the OFF condition.

In step 825, depressing pushbutton switch 157 wakens the controller 620 from its sleep state (forces a pin P3 enabled interrupt) and program flow continues to step 826. Controller 620 then begins to execute the steps beginning with step 902 in FIG. 20A.

Referring to FIGS. 20A-20D, the operational flowchart 900 for test probe 10 is shown and begins with entry point ‘A’ 826. Entry point ‘A’ 826 is entered after having controller 620 first placed in the sleep mode as indicated in step 824 (see FIG. 19) and then afterwards having pushbutton 157 depressed. Program flow then continues to step 902.

In step 902, controller 620 exists from sleep mode and disables the pushbutton interrupt. Program flow continues to step 906.

In step 906, controller 620 turns on the load circuit 614 by outputting the load circuit enable signal 642 and turns on the voltage sensing circuit 608 and voltage limited power source 610 by setting pin P1 high (the second control signal 650 then also goes high) to turn ON transistors Q2 and Q3. The low battery flag is reset. Program flow then continues to step 910.

In step 910, controller 620 inputs the sensed battery voltage signal 637 placed on pin P2 from voltage sensing circuit 608. Program flow then continues to step 912.

In step 912, controller 620 determines if the sensed voltage signal 637 is less than or equal to a preprogrammed threshold voltage Vth(2). If the sensed voltage signal 637 is less than or equal to Vth(2), program flow then continues to step 916. Otherwise, program flow continues to step 918.

In step 916, controller 620 sets a low battery flag. Program then flows to step 918.

In step 918, controller 620 determines if pushbutton switch 157 is depressed. If pushbutton switch 157 is depressed, program flow continues to step 922. If the pushbutton 157 is not depressed, program flow continues to the beginning of step 918.

In step 922, controller 620 initializes and starts its internal timer 623. The timer 623 may be the TCA0 timer of a ATtiny417 controller. Program then flows to step 924.

In step 924, controller 620 determines if the pushbutton switch 157 is depressed. If pushbutton switch 157 is depressed program flow continues to step 928. If pushbutton switch 157 is not depressed, program flow continues to ‘C’ 926 in FIG. 20B.

In step 928, controller 620 determines if the low battery flag has been set. If the battery flag has been previously set in step 916, program flow continues to step 930. Otherwise, if the low battery flag has not been set, program flow continues to step 932.

In step 930, controller 620 turns on red LED 134 via the red LED control signal 644 which turns on transistor Q7. Program flow continues to step 932.

In step 932, controller 620 turns on LED array circuit 626 having an intensity level of ‘Ix’ with LED array control signal 646. The LED array control signal 646 value has been previously preprogrammed into the memory of controller 620 for setting the intensity of the LED array to the desired intensity value Ix. Program flow then continues back to step 924.

Program flow continues to step 928 (from ‘C’ 926 (FIG. 20A), in which controller 620 determines if the timer 623 has timed out. If the timer 623 has timed out, program flow continues to step 930.

In step 930, controller 620 turns off the LED array circuit 626 and the red LED 134. Program flow then continues to step 932.

In step 932, controller 620 stops and resets timer 623. Program flow continues to ‘B’ 830 in FIG. 19.

In step 934, controller 620 determines if the pushbutton switch 157 is depressed. If the pushbutton switch 157 is depressed, program flow continues to step 938. If the pushbutton 157 is not depressed, program flow continues to ‘D’ 936 and loops back to the beginning of step 928.

In step 938, controller 620 determines if the pushbutton switch 157 is depressed. If the pushbutton switch 157 is depressed, program flow continues to step 940. If the pushbutton 157 is not depressed, program flow continues to ‘E’ 942 in FIG. 20C. Program flow continues from ‘E’ 942 to step 955 in FIG. 20C.

In step 940, controller 620 determines if its internal timer 623 has timed out. If the timer 623 has timed out, program flow continues to step 944. If the timer 623 has not timed out, program flow loops back to the beginning of step 938.

In step 944, controller 620 determines if the pushbutton switch 157 is depressed. If the pushbutton switch 157 is depressed, program flow loops back to the beginning of step 944. If the pushbutton is not depressed, program flow continues to step 948.

In step 948, controller 620 shuts off the LED array circuit 626 and the red LED 134. Program flow then continues to step 950.

In step 950, controller 620 stops and resets its internal timer 623. Program flow then continues to ‘B’ 830 and loops back to the beginning of step 822 in FIG. 19.

In step 955 in FIG. 20C, controller 620 sets the LED array intensity value to Ix by outputting an analog voltage on the led array control signal 646 from its internal digital-to-analog converter 622. Signal 646 controls the current source transistor Q6 which is configured as a voltage controlled current source and subsequently sets the current flow through the LED array diodes 381a, b, c, and d and thus sets the light intensity incident upon the test pin tip 403 and the circuit test point. Program flow continues to step 958.

In step 958, controller 620 blinks LED array at an intensity value of Ix by outputting the corresponding led array control signal 646. Program flow then continues to step 960.

In step 960, controller 620 determines if the pushbutton switch 157 is depressed. If the pushbutton switch 157 is depressed, program flow continues to step 962. If the pushbutton switch 157 is not depressed, program flow continues to step 964.

In step 964, controller 620 determines if the array LEDs 381a, b, c, and d have been blinked three times. If the array LEDs 381a, b, c, and d have been blinked three times, program flow continues to step 962. If the array LEDs 381a, b, c, and d have not been blinked three times, program flow loops back to step 958.

The loop of step 958, step 960, and step 964 (and the blinking of the array LEDs 381a, b, c, and d) inform the user that the future intensity of the array LEDs 381a, b, c, and d may be changed and programmed by the user.

In step 962, controller 620 determines if the pushbutton switch 157 is depressed. If the pushbutton 157 is depressed, program flow continues to step 970. If the pushbutton switch is not depressed, program flow continues to step 972.

In step 972, controller 620 stops and resets its timer 623, and turns OFF array LEDs 381a, b, c, and d and red LED 134 by outputting the OFF signals 646 and 644. Program flow then continues to ‘B’ 830 and then to step 822 in FIG. 19.

In step 970. Controller 620 sets array LEDs 381a, b, c, and d to intensity value I1. Program flow continues to step 974.

In step 974, controller 620 executes a delay of 750 ms. Program flow continues to step 978.

In step 978, controller 620 determines if pushbutton switch 157 is depressed. If the pushbutton 157 is depressed, program flow continues to step 980. If the pushbutton switch is not depressed, program flow continues to step 982.

In step 980, controller 620 sets the intensity of the array LEDs 381a, b, c, and d to intensity value 12. Program flow continues to step 984.

In step 984, controller 620 executes a delay of 750 ms. Program flow continues to ‘G’ 988 and then to step 990 in FIG. 20D.

In step 982, controller 620 sets the intensity of the array LEDs 381a, b, c, and d to I1. Program flow continues back to step 972 via ‘F’ 986.

Referring to FIG. 20D and in step 990, controller 620 determines if pushbutton switch 157 is depressed. If the pushbutton 157 is depressed, program flow continues to step 991. If the pushbutton switch is not depressed, program flow continues to step 992.

In step 991, controller 620 sets the intensity of the array LEDs 381a, b, c, and d to I3. Program flow continues to step 993.

In step 992, controller 620 sets the intensity of the array LEDs 381a, b, c, and d to I2. Program flow then continues back to step 972 via ‘F’ 986 in FIG. 20C.

In step 993, controller 620 executes a delay of 750 ms. Program flow continues to step 994.

In step 994, controller determines if pushbutton switch is depressed. If the pushbutton 157 is depressed, program flow continues to step 962 via ‘H’ 996 in FIG. 20C. If the pushbutton switch is not depressed, program flow continues to step 995.

In step 995, controller 620 sets the intensity of the array LEDs 381a, b, c, and d to I3. Program flow continues to step 972 via ‘F’ 986 in FIG. 20C.

In steps 978, 990, and 994 the user may select the desired intensity illumination level for the array LEDs 381a, b, c, and d by maintaining the depression of switch 157 for a duration of time and then releasing the pushbutton switch 157, thus programming the illumination intensity for any future applications of probe 10.

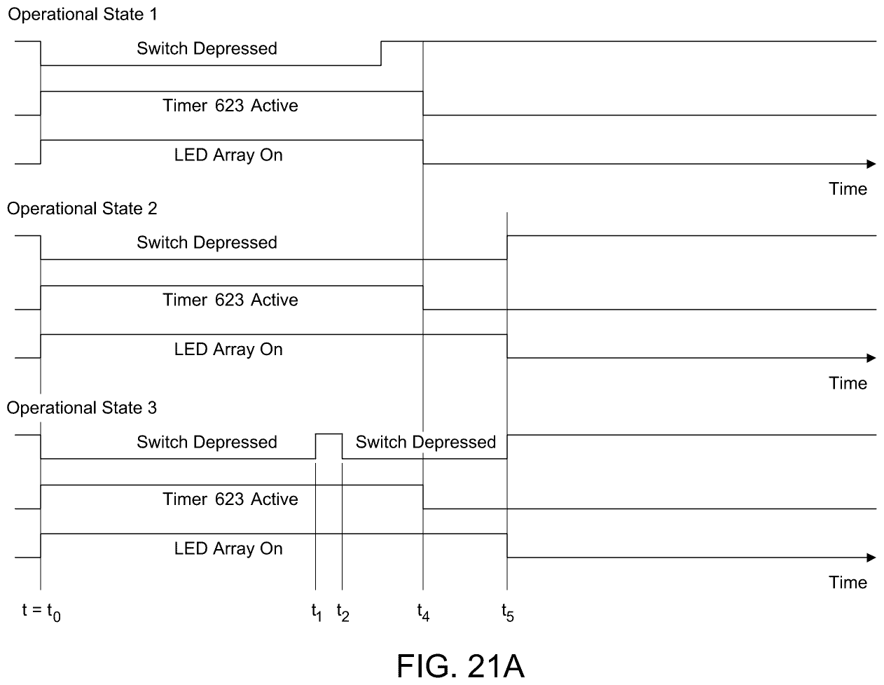

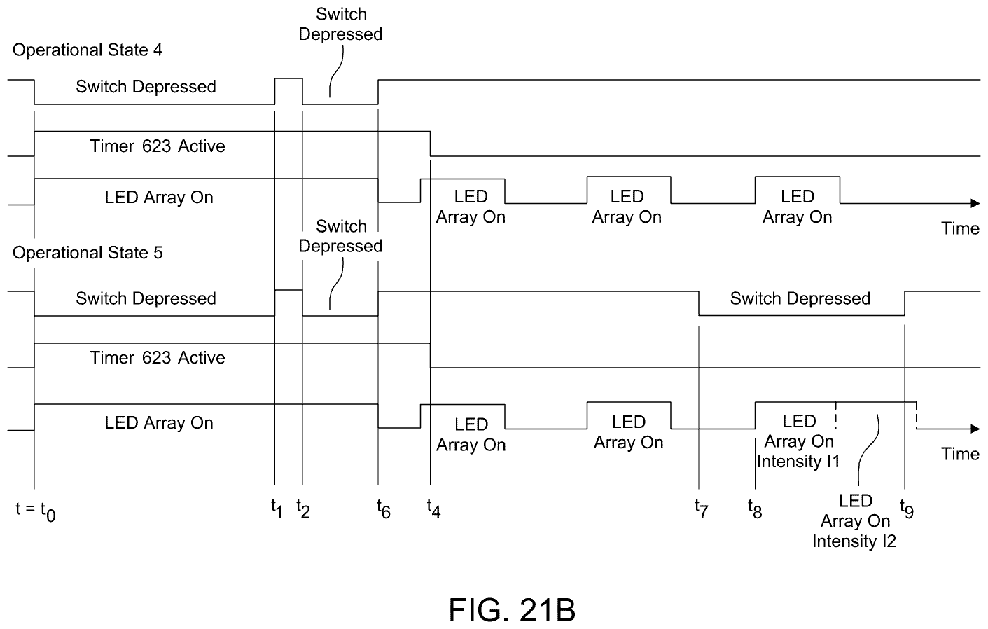

In operation and additionally referring to FIGS. 21A and 21B, the timing diagrams of the operational states of the electrical circuit test probe 10 are shown and comprise the operational states 1-5. Operational states 1-3 (FIG. 21A) represent the operational states during normal operation of probe 10, i.e., during those times that the probe is used for testing electrical circuits. Operational states 4-5 (FIG. 21B) represent the operational states for programming the illumination intensity of probe 10.

The timing diagrams of the operational states illustrate along the vertical axes the states of pushbutton switch 157 (depressed or not depressed), the timer 623 (timer active or timed out), and the LED array 377 (LED diodes 381a, b, c, and d are ON or OFF) as functions of time (the horizontal axes in FIGS. 21A and 21B represents time).

In the following discussions, it is assumed that for times t<to all operational states 1-5 begin with the controller 620 in a sleep mode as defined in step 824 (see FIG. 19) and is awaiting the depression of the pushbutton switch 157 to exit the sleep mode and begin program execution in step 902 (see FIG. 20A).

Further, all operational states 1-5 execute steps 902 through 922 as previously described.

In step 918 the controller 620 determines if pushbutton 157 is depressed. In all the operational state timing diagrams, the beginning execution of step 922 is defined as t=to.

For the operational normal state 1 and in step 922, the pushbutton switch 157 has been previously depressed in step 918 and the controller 620 initializes and starts its internal timer 623. The timer 623 has a timer period of t4 seconds. If the user releases the pushbutton switch 157 before the timer 623 has timed out, the LED array diodes 381a, b, c, and d remain ON until the timer 623 times out at which time the LED array diodes are shut OFF by controller 620 via the LED array control signal 646. Operational state 1 enables the user to quickly depress and release the pushbutton switch 157 to illuminate a test area for a period of t4 seconds without having to continuously depress pushbutton 157.

For the operational normal state 2 and in step 922, the pushbutton switch 157 has been previously depressed in step 918 and the controller 620 initializes and starts its internal timer 623. The timer 623 has a timer period of t4 seconds. If the user continues to depress the pushbutton switch 157 after the timer 623 has timed out for example to time t5, the LED array diodes 381a, b, c, and d remain ON until the user releases the pushbutton 157 at which time the LED array diodes 381a, b, c, and d are shut OFF by controller 620 via the LED array control signal 646. Operational state 2 enables the user to maintain test contact point illumination beyond the timer period t4 seconds by continuously depressing pushbutton 157. Upon releasing the pushbutton 157, the LED array diodes 381a, b, c, and d are shut OFF by controller 620 via the LED array control signal 646.

For the operational normal state 3 and in step 922, the pushbutton switch 157 has been previously depressed in step 918 and the controller 620 initializes and starts its internal timer 623. The timer 623 has a timer period of t4 seconds. If the user releases the pushbutton 157 at t1 and then depresses the pushbutton switch 157 at t2 before the timer 623 has timed out, the LED array diodes remain ON until the user releases the pushbutton 157 at t5 at which time the LED array diodes 381a, b, c, and d are shut OFF by controller 620 via the LED array control signal 646. Operational state 3 enables the user to accidently release and then immediately depress the pushbutton switch 157 without losing test point contact illumination.

The duration of the switch 157 depression determines the period of illumination in operational states 2 and 3.

For the operational programing state 4 and in step 922, the pushbutton switch 157 has been previously depressed in step 918 and the controller 620 initializes and starts its internal timer 623. The timer 623 has a timer period of t4 seconds. If the user releases the pushbutton 157 at t1 then depresses the pushbutton switch 157 at t2 and then release the pushbutton switch 157 at t6 before the timer 623 has timed out, the controller 620 enters the programming mode for the user to set the illumination level for the LED array diodes 381a, b, c, and d.

The controller 620 then blinks the LED array up to 3 times to inform the user that the probe may be programmed to program the illumination level for further test probing sessions.

If the user does not desire to program the illumination level of the LED array 377 diodes 381a, b, c, and d, the user does not further depress the pushbutton switch 157. The controller 620 then completes the 3-blink sequence of the LED array diodes 381a, b, c, and d, stops and resets the timer 623 and turns off the LED array diodes 381a, b, c, and d returning to step 822 via ‘B’ 830.

For the operational programing state 5, the illumination level for the LED array diodes 381a, b, c, and d are programmed for all subsequent test probing sessions unless the user desires to reprogram the LED array illumination by executing another operational programing state 5.

Operational programming state 5 is entered from the operational programing state 4. During the blinking of the LED array diodes 381a, b, c, and d in operational programming state 4 if the user depresses pushbutton switch 157 at t7 the controller 620 begins to adjust the control signal 646 to sequentially adjust the LED array intensity at t=t8 from the lowest preprogrammed value (I1) to the highest preprogrammed value (I6). At the desired illumination level, the user releases the pushbutton switch 157 at t=t9 and the controller 620 then sets the intensity value at the desired value for all further illuminations (unless the user desires to reprogram the illumination levels by entering operational programming state 5 again). Upon the user releasing the switch 157 at time t=t9, the controller 620 programs the intensity of the LED array 377 at the I2 value.

The number of the switch 157 depressions within a period determines if the controller 620 initiates operational state 4 and the duration of switch 157 depression determines the intended intensity level for the LED diodes 381a, b, c, and d in operational state 5.

Thus, controller 620 is configured to program the intensity of the LED array diodes 381a, b, c, and d depending upon the number of pushbutton switch 157 depressions and the duration of the pushbutton 157 switch depressions.

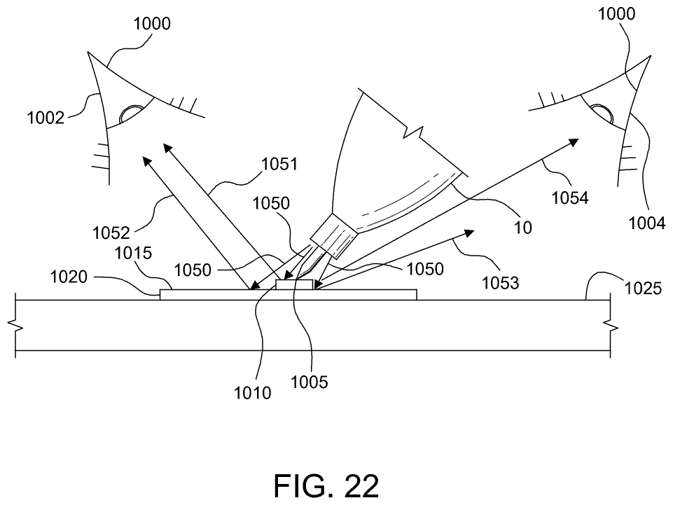

Referring to FIG. 22, the probe 10 and the human eye 1000 is shown in two relative orientations 1002 and 1004 of the eye 1000 with respect to the probe 10 for measuring electrical phenomenon of circuit test point 1005. The circuit test point 1005 may be a conductor 1010 located on the top surface 1015 of printed circuit board 1020 or a pin of an integrated circuit. The printed circuit board 1020 is shown positioned on a work table 1025.

As shown, the orientation 1002 of probe 10 with respect to the eye 1000 causes the incident light rays 1050 to reflect from the circuit test point 1005. Some of the incident light rays 1050 reflect off the area surrounding the circuit test point 1005 and back to the eye 1000 as reflected rays 1051 and 1052, and some of the incident rays 1050 are also reflected away from the eye 1000 as reflected rays 1053 and 1054.

The incident and reflected rays all obey the law of reflection, and therefore the image of the circuit test point 1005 will appear brighter to the user for orientation 1002 than those back reflected rays 1053 and 1054 when viewed from orientation 1004.

For orientation 1002 it may be beneficial for the user to decrease the intensity of the illumination (and possibly reduce glare) and for orientation 1004 it may be beneficial for the user to increase the illumination intensity.

Although illustrated and described above with reference to certain specific embodiments, the present invention is nevertheless not intended to be limited to the details shown. The scope of the invention is defined in the appended claims.

1. -25. (canceled)

26. An electrical circuit test probe comprising:
a housing having a first longitudinal axis;
a pin protruding from one end of the housing for making electrical contact with the electrical circuit;
a lens; and
a lens positioning system rotatably affixed to the housing about the first longitudinal axis and configured for providing an unobstructive view of the pin making electrical contact with the electrical circuit.

27. The electrical circuit test probe of claim 26, wherein the lens positioning system further comprises:
a lens mount assembly rotatably affixed to the housing having an axis of rotation coincident with the longitudinal first axis; and
a lens support assembly affixed to the lens mount assembly, the lens support assembly pivotally supporting the lens about a second axis of rotation wherein the second axis of rotation is perpendicular to the first longitudinal axis.

28. The electrical circuit test probe of claim 27, wherein the lens support assembly is removably affixed to the lens mount assembly.

29. The electrical circuit test probe of claim 28, wherein the lens support assembly is magnetically affixed to the lens mount assembly.

30. The electrical circuit test probe of claim 27, wherein the housing further comprises a fixed elastomer element, the housing and elastomer element configured to frictionally engage the lens mount assembly.

31. The electrical circuit test probe of claim 30, wherein the elastomer element is an O-ring.

32. A system for measuring physical phenomena comprising:
a measuring instrument configured to measure the physical phenomena;
a probe having a housing and coupled to the measuring instrument for providing a representation of the physical phenomena at a test point;
a lens; and
a lens positioning system attached to the housing for supporting the lens and configured to provide an unobstructive view of the test point.

33. The system of claim 32, wherein the lens positioning system further comprises:
a lens mount assembly rotatably affixed to the housing having an axis of rotation coincident with the longitudinal first axis of the housing; and
a lens support assembly affixed to the lens mount assembly, the lens support assembly pivotally supporting the lens about a second axis of rotation wherein the second axis of rotation is perpendicular to the first longitudinal axis.

34. The system of claim 33, wherein the lens support assembly is removably affixed to the lens mount assembly.

35. The system of claim 33, wherein an elastomer element is affixed to the housing, the housing and elastomer element configured to frictionally engage the lens mount assembly.

36. The system of claim 35, wherein the elastomer element is an O-ring.

37. A circuit for protecting a battery powered test probe circuit comprising:
a first switch coupled to the battery for delivering electrical power and responsive to the polarity of the battery voltage;
a second switch coupled to the first switch and responsive to a first control signal for delivering electrical power;
a voltage limited first power source coupled to the first switch for delivering voltage limited electrical power and responsive to a second control signal;
a voltage sensing circuit coupled to the first switch for sensing the voltage level of power being delivered by the first switch and responsive to the second control signal;
a second power source coupled to the second switch and coupled to the voltage limited power source, the second power source responsive to an enable signal; and
a controller powered by the voltage limited power source and selectively powered from the second switch, the controller configured to be responsive to the voltage sensing circuit and for providing the first control signal, the second control signal, and the enable signal.

38. The circuit of claim 37, wherein the voltage limited first power source is configured to deliver voltage limited electrical power to the controller immediately upon receiving electrical power from the first switch.

39. The circuit of claim 37, wherein the voltage sensing circuit is configured to sense the voltage level of power being delivered by the first switch immediately upon receiving electrical power from the first switch.

40. The circuit of claim 37, wherein the controller is configured to receive the sensed voltage from the voltage sensing circuit and determine if the sensed voltage is less than a threshold value.

41. The circuit of claim 37, the second power source further comprises a switching regulator circuit.
